(19) United States
(12) Patent Application Publication
(10) Pub. No.: US 2025/0355369 A1
(43) Pub. Date: Nov. 20, 2025

(54) MARK MEASUREMENT METHOD, MEASUREMENT DEVICE, LITHOGRAPHY DEVICE, CALCULATOR, AND STORAGE MEDIUM

(71) Applicant: NIKON CORPORATION, Tokyo (JP)

(72) Inventors: Satoshi ANDO, Tokyo (JP); Heisuke ISHINO, Tokyo (JP)

(73) Assignee: NIKON CORPORATION, Tokyo (JP)

(21) Appl. No.: 19/285,542

(22) Filed: Jul. 30, 2025

Related U.S. Application Data
(63) Continuation-in-part of application No. PCT/JP2023/003023, filed on Jan. 31, 2023.

(51) Int. Cl. G03F 7/00

(52) U.S. Cl. CPC G03F 7/70633; G03F 7/706837; G03F 7/70725; G03F 7/70775

(57) ABSTRACT

A measurement method including: acquiring an image of an overlay mark formed by overlaying a first pattern in which a line-and-space is repeatedly formed at a first pitch P1 in a predetermined direction in a layer on a substrate and a second pattern in which a line-and-space is repeatedly formed at a second pitch P2 different from the first pitch P1 in the predetermined direction in another layer different from the layer; extracting a luminance signal of the overlay mark in the predetermined direction from the acquired image of the overlay mark; and determining an absolute position of at least one of the first pattern and the second pattern in the predetermined direction from the extracted luminance signal.

### BACKGROUND OF THE INVENTION

### Field of the Invention

The present invention relates to a mark measurement method, a measurement device, a lithography device, a calculator, and a storage medium.

### CROSS-REFERENCE TO RELATED APPLICATIONS

This application claims the benefit of and incorporates by reference the entire disclosure of PCT Patent Application No. PCT/JP2023/003023, filed on Jan. 31, 2023, the contents of which are hereby incorporated by reference in their entirety.

### Description of the Related Art

In a lithography process for manufacturing a semiconductor element or the like, a semiconductor element or the like is formed by overlaying a multilayer circuit pattern on a substrate such as a wafer or a glass plate. However, when the overlay accuracy between the layers is poor, the semiconductor element or the like cannot exhibit predetermined circuit characteristics, and in some cases, the manufactured semiconductor element or the like becomes defective. For this reason, an overlay mark constituted by patterns formed in different two layers is imaged, and the overlay accuracy between the different two layers is measured from the image.

For example, Patent Document 1 discloses an overlay mark measurement method of acquiring an image of an overlay mark, and acquiring the relative positional deviation amount between the first pattern formed in the first layer and the second pattern formed in the second layer from the acquired image.

### PRIOR ART DOCUMENT

### Patent Document

Patent Document 1: JP-A-2004-508711

### SUMMARY OF THE INVENTION

As patterns become finer, demands for mark measurement from the market are increasing. Also in the overlay mark measurement, it is required to reduce the size of the overlay mark, increase the measurement speed, or improve the measurement accuracy. An object of the present invention is to provide an improved overlay mark measurement method that meets at least one of these requirements.

In the present disclosure, an overlay mark formed by overlaying patterns formed in different two layers is measured. The phrase “overlaying patterns formed in different two layers” means that at least a part of the region of a pattern formed in a layer and at least a part of the region of another layer are stacked in the direction perpendicular to the substrate surface. Such overlay marks include a variety of kinds. Examples thereof include: a diffraction based overlay mark (DBO mark) in which the overlay mark formed by overlaying diffracts light, and the light is detected to determine the deviation of the two layers; and a fringe based overlay mark (hereinafter, referred to as “FBO mark”) in which a moire pattern formed by overlaying is detected to determine the deviation of the two layers. The FBO mark is designed to intentionally overlay patterns formed in different two layers to form a moire pattern. Note that the FBO marks do not include a mark that is not designed to intentionally overlay patterns formed in different two layers, for example, a mark that is not overlaid without an alignment error, but overlaid when there is a significant alignment error.

The present inventors have created a measurement method for detecting the absolute position of the patterns in each layer constituting an FBO mark. The absolute position refers to the shift position of an overlay mark from a coordinate origin, which is any point in the measurement device. In the present specification, measurement for detecting the absolute position of a pattern is referred to as “absolute position measurement” of the pattern. The absolute position measurement has a measurement concept that is greatly different from the conventionally known relative position measurement, in which the relative position deviation amount between patterns is detected. Advantages of the absolute position measurement will be described later.

According to one embodiment of the measurement method including:
acquiring an image of an overlay mark formed by overlaying a first pattern in which a line-and-space is repeatedly formed at a first pitch P1 in a predetermined direction in a layer on a substrate and a second pattern in which a line-and-space is repeatedly formed at a second pitch P2 different from the first pitch P1 in the predetermined direction in another layer different from the layer;
extracting a luminance signal of the overlay mark in the predetermined direction from the acquired image of the overlay mark; and
determining an absolute position of at least one of the first pattern and the second pattern in the predetermined direction from the extracted luminance signal.

In this specification, a pattern formed in a layer refers to a pattern formed within the layer. A pattern formed in another layer refers to a pattern formed within the another layer.
the overlay mark may include:
a first region including a first overlay mark in which the first pattern is formed below the second pattern, and the formed second pattern is overlaid on the first pattern; and
a second region including a second overlay mark in which the first pattern is formed above the second pattern, and the formed first pattern is overlaid on the second pattern; and
the determining an absolute position of at least one of the first pattern and the second pattern in the predetermined direction from the extracted luminance signal includes:
determining a first moire position X1 in the predetermined direction of a moire image formed in the first region by overlaying the first pattern and the second pattern from the luminance signal of the first overlay mark; and
determining a second moire position X2 in the predetermined direction of a moire image formed in the second region by overlaying the second pattern and the first pattern from the luminance signal of the second overlay mark.
the first pitch P1 and the second pitch P2 may be smaller than a resolution limit of an imaging unit that images the overlay mark.

The measurement method may include at least one of:
determining an absolute position AP1 in the predetermined direction of the pattern formed above from a formula (3); and
determining an absolute position AP2 in the predetermined direction of the pattern formed below from a formula (4).

$$AP 1 = \frac{P 1 X 1 + P 2 X 2}{P 1 + P 2} \qquad ( 3 )$$

$$AP 2 = \frac{P 2 X 1 + P 1 X 2}{P 1 + P 2} \qquad ( 4 )$$

According to one embodiment of the measurement method including:
acquiring an image of an overlay mark formed in a first region by overlaying a first pattern in which a line-and-space is repeatedly formed at a first pitch P1 in a predetermined direction in a layer on a substrate and a second pattern in which a line-and-space is repeatedly formed at a second pitch P2 different from the first pitch P1 in the predetermined direction in another layer different from the layer;
acquiring an image of an overlay mark formed in a second region by overlaying a third pattern in which a line-and-space is repeatedly formed at a third pitch P3 in the predetermined direction in the layer and a fourth pattern in which a line-and-space is repeatedly formed at a fourth pitch P4 different from the third pitch P3 in the predetermined direction in the other layer;
extracting a first luminance signal that is a luminance signal in the predetermined direction of the overlay mark formed in the first region from the acquired image of the overlay mark in the first region;
extracting a second luminance signal that is a luminance signal in the predetermined direction of the overlay mark formed in the second region from the acquired image of the overlay mark in the second region; and
determining an absolute position in the predetermined direction of at least one of the first pattern, the second pattern, the third pattern, and the fourth pattern from the extracted first luminance signal and second luminance signal.

The measurement method may include the determining an absolute position in the predetermined direction of at least one of the first pattern, the second pattern, the third pattern, and the fourth pattern from the extracted first luminance signal and second luminance signal includes:
determining a first moire position X1 in the predetermined direction of a moire image formed in the first region by the first pattern and the second pattern from the first luminance signal; and
determining a second moire position X2 in the predetermined direction of a moire image formed in the second region by the third pattern and the fourth pattern.

The measurement method may include at least one of: determining an absolute position AP1 in the predetermined direction of the second pattern or the fourth pattern formed in the other layer from a formula (7); and
determining an absolute position AP2 in the predetermined direction of the first pattern or the third pattern formed in the layer from a formula (8).

$$AP 1 = \frac{P 4 ( P 2 - P 1 ) X 1 + P 2 ( P 3 - P 4 ) X 2}{P 2 P 3 - P 1 P 4} \qquad ( 7 )$$

$$AP 2 = \frac{P 3 ( P 2 - P 1 ) X 1 + P 1 ( P 3 - P 4 ) X 2}{P 2 P 3 - P 1 P 4} \qquad ( 8 )$$

The measurement method may include the determining the first moire position in the predetermined direction or the second moire position in the predetermined direction from the luminance signal includes:
a. cutting out a signal length that is positive integer times a period of the moire image from the luminance signal;
b. preparing a basis function of a signal of the moire image;
c. calculating an inner product of the cut-out luminance signal and the basis function in a range of the cut-out signal length;
d. acquiring a frequency component of a signal of the moire image from a calculation result of the inner product to detect a phase of the acquired frequency component; and
e. determining the first moire position or the second moire position from the detected phase.

The measurement method may include the determining an absolute position in the predetermined direction of at least one of the first pattern and the second pattern from the extracted luminance signal includes at least one of: separating a luminance signal of the first pattern; and separating a luminance signal of the second pattern, from the luminance signal.

The measurement method may include the separating at least one of a luminance signal of the first pattern and a luminance signal of the second pattern, from the luminance signal, includes:
a. cutting out a signal length that is positive integer times a period of the pattern to be separated from the luminance signal;
b. preparing a basis function of a luminance signal of the pattern to be separated;
c. calculating an inner product of the cut-out luminance signal and the basis function in a range of the cut-out signal length; and
d. acquiring a frequency component of a luminance signal of the pattern to be separated from a calculation result of the inner product.

The measurement method may further include: resampling the luminance signal with a data pitch, wherein the data pitch is smaller than ½ of a period of the pattern to be separated, and a positive integral multiple of the data pitch is equal to a positive integral multiple of a period of the pattern to be separated.

The measurement method may include: the basis function is a sine function.

The measurement method may include:
detecting a phase from the acquired frequency component of a luminance signal of the pattern to be separated; and
determining an absolute position of the pattern from the detected phase.

A measurement method including:
generating a luminance signal in a predetermined direction of an overlay mark formed by overlaying a first pattern in which a line-and-space is repeatedly formed at a first pitch P1 in the predetermined direction in a layer on a substrate and a second pattern in which a line-and-space is repeatedly formed at a second pitch P2 different from the first pitch P1 in the predetermined direction in another layer different from the layer;
separating and extracting a luminance signal of the first pattern from the luminance signal; and
calculating an absolute position of the first pattern based on the extracted luminance signal of the first pattern.

The measurement method may include: the overlay mark is formed by overlaying the first pattern and the second pattern in a common first region.

The measurement method may include: the separating and extracting a luminance signal of the first pattern includes:
cutting out a signal length that is positive integer times the first pitch from the luminance signal;
preparing a basis function of a luminance change of the first pattern; and
calculating an inner product of the luminance signal and the basis function in a range of the cut-out signal length.

The measurement method may include: acquiring a frequency component of a luminance signal of the first pattern from a calculation result of the inner product; and detecting a phase of the acquired frequency component to calculate an absolute position of the first pattern.

The measurement method may include: a first absolute position of the first pattern in the predetermined direction and a second absolute position of the second pattern in the predetermined direction are determined from the extracted luminance signal, and a relative positional deviation amount in the predetermined direction between the first pattern and the second pattern is calculated from the first absolute position and the second absolute position.

The measurement method may include: the predetermined direction including: a first direction; and a second direction intersecting the first direction, the measurement method including:
determining an absolute position in the first direction of at least one of the first pattern and the second pattern by using the measurement method; and
determining an absolute position in the second direction of at least one of the first pattern and the second pattern by using the measurement method.

The measurement method may include:
a relative positional deviation amount in the first direction between the first pattern and the second pattern is calculated from the absolute positions in the first direction of the first pattern and the second pattern, and
a relative positional deviation amount in the second direction between the first pattern and the second pattern is calculated from the absolute positions in the second direction of the first pattern and the second pattern.

A measurement device including:
a stage on which the substrate having the formed overlay mark is arranged;
an imaging unit configured to image the overlay mark; and
a controller that measures and controls an absolute position of at least one of the first pattern and the second pattern by performing the measurement method according to claim 1, based on an image of the overlay mark imaged by the imaging unit.

A lithography device including:
a stage on which the substrate having the formed overlay mark is arranged;
an imaging unit configured to image the overlay mark; and
a controller that measures and controls an absolute position of at least one of the first pattern and the second pattern by performing the measurement method according to claim 1, based on an image of the overlay mark imaged by the imaging unit.

23. A calculator including:
an input unit configured to input information regarding an image of the overlay mark formed on the substrate;
a calculation unit configured to calculate an absolute position of at least one of the first pattern and the second pattern by performing the measurement method according to claim 1; and
an output unit configured to output information regarding an absolute position of at least one of the first pattern and the second pattern calculated by the calculation unit.

A storage medium storing a program by which a measurement device or a lithography device performs the measurement method.

A measurement method including:
receiving light from a first pattern formed in a first layer and repeating a line-and-space in a predetermined direction at a first pitch P1 and light from a second pattern formed in a second layer overlaid on the first layer and repeating a line-and-space in the predetermined direction at a second pitch P2 different from the first pitch P1 to acquire a first image; and
outputting information regarding a position of at least one pattern of the first pattern and the second pattern in the predetermined direction with respect to a predetermined coordinate of a device with which the first image is acquired, based on the first image.

The measurement method may include: the first image has a periodic luminance in the predetermined direction.

The measurement method may include:
receiving light from a third pattern formed in the first layer and repeating a line-and-space in the predetermined direction at a third pitch P3 and light from a fourth pattern formed in the second layer and repeating a line-and-space in the predetermined direction at a fourth pitch P4 different from the third pitch P3 to acquire a second image having a periodic luminance in the predetermined direction, wherein
the information includes information regarding a position of the at least one pattern in the predetermined direction with respect to the predetermined coordinate, based on the first image and the second image.

The measurement method may include: a position of the luminance of the first image in the predetermined direction with respect to the predetermined coordinate being defined as X1, and a position of the luminance of the second image in the predetermined direction with respect to the predetermined coordinate being defined as X2,
wherein the outputting information includes at least one of: determining a position AP1 of the first pattern in the predetermined direction with respect to the predetermined coordinate from a formula (7); and determining a position AP2 of the second pattern in the predetermined direction with respect to the predetermined coordinate from a formula (8).

$$AP 1 = \frac{P 4 ( P 2 - P 1 ) X 1 + P 2 ( P 3 - P 4 ) X 2}{P 2 P 3 - P 1 P 4} \qquad ( 7 )$$

$$AP 2 = \frac{P 3 ( P 2 - P 1 ) X 1 + P 1 ( P 3 - P 4 ) X 2}{P 2 P 3 - P 1 P 4} \qquad ( 8 )$$

A device may include:
a stage on which a substrate having the first layer and the second layer is arranged; and
an imaging element configured to receive the light from the first pattern and the light from the second pattern, wherein
the device performs the measurement method.

A manufacturing method may include: manufacturing a semiconductor device having two or more layers each having a pattern by using the measurement method.

### BRIEF DESCRIPTION OF THE DRAWINGS

FIG. 1 is a conceptual diagram of an overlay mark and a process of forming the same;

FIG. 2 is a partially enlarged cross-sectional view of a first overlay mark in the overlay mark of FIG. 1;

FIG. 3 is a partially enlarged cross-sectional view of a second overlay mark in the overlay mark of FIG. 1;

FIG. 4 is a diagram for explaining advantages of absolute value measurement;

FIG. 5 is a diagram showing an overlay mark and the luminance signal of an image of the overlay mark;

FIG. 6 is a diagram for explaining the separation of a luminance signal;

FIG. 7A is a flowchart showing a method for extracting the frequency component of a pattern to be extracted from a luminance signal;

FIG. 7B is a diagram for explaining the separation of a luminance signal using the inner product method;

FIG. 8 is a conceptual diagram of an overlay mark in another embodiment and a process of forming the same;

FIG. 9 is a partially enlarged cross-sectional view of a first overlay mark in the overlay mark of FIG. 8;

FIG. 10 is a partially enlarged cross-sectional view of a fourth overlay mark in the overlay mark of FIG. 8;

FIG. 11 is a cross-sectional view of a first reference wafer;

FIG. 12 is a cross-sectional view of a second reference wafer;

FIG. 13 is a cross-sectional view of a third reference wafer;

FIG. 14A is a front view (a view seen from the −Y direction) of a measurement device;

FIG. 14B is a cross-sectional view of a measurement device in the XZ plane;

FIG. 15 is a cross-sectional view of a measurement device in the YZ plane;

FIG. 16 is a block diagram showing the input/output relationship of a controller mainly constituting the control system of a measurement device;

FIG. 17 is a schematic diagram of a lithography device; and

FIG. 18 is a block diagram showing the input/output relationship of a lithography controller equipped in a lithography device.

### DETAILED DESCRIPTION OF THE PREFERRED EMBODIMENTS

Hereinafter, embodiments for carrying out the invention will be described with reference to the drawings. The drawings are illustrated schematically. A dimensional ratio and a number illustrated in the drawings do not necessarily coincide with the actual dimensional ratio and number. The drawings are illustrated using the XYZ coordinate system as appropriate. The specification will be described with reference to the XYZ coordinate system as appropriate. In the present specification, when a direction is expressed with the positive and negative directions, the direction is described with positive and negative signs, such as “+X direction” and “−X direction”. When a direction is expressed without the positive and negative directions, the direction is simply described as “X direction”. That is, in the present specification, when simply described as “X direction”, the direction includes both “+X direction” and “−X direction”. The same applies to the Y direction and the Z direction.

### First Embodiment

A first embodiment of the mark measurement method will be described.

### [Overlay Mark]

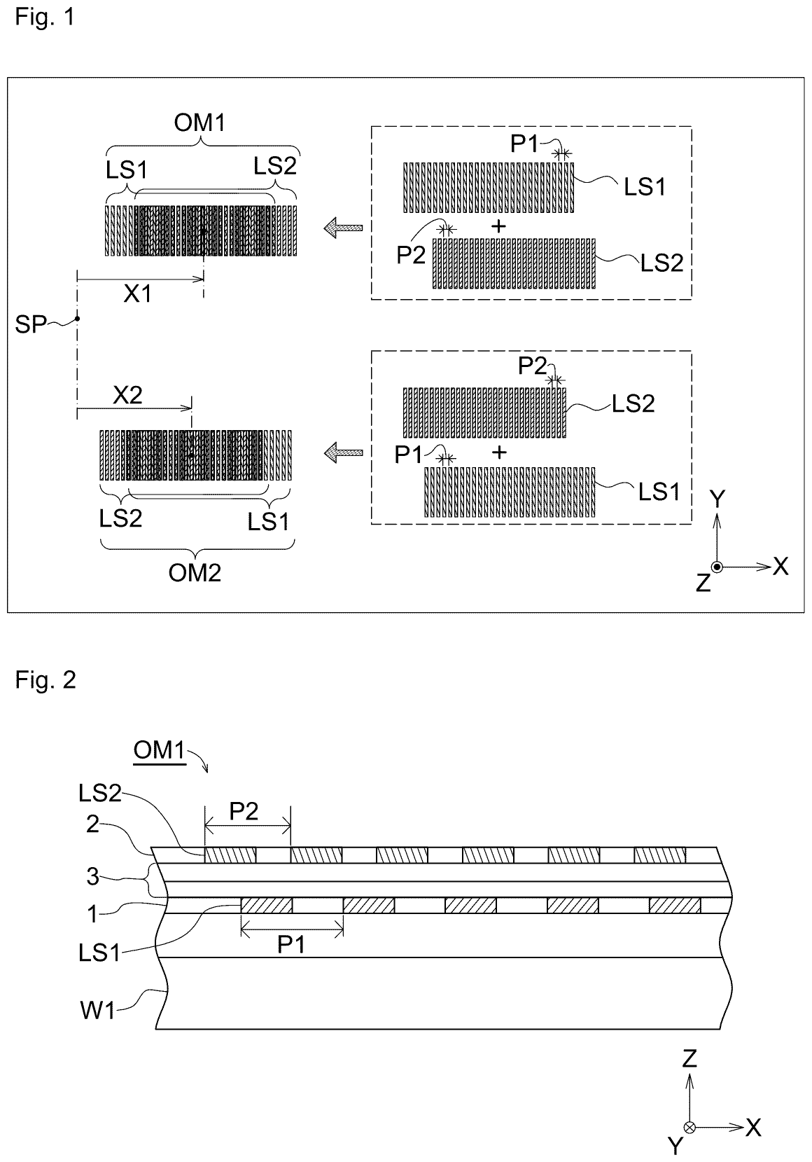

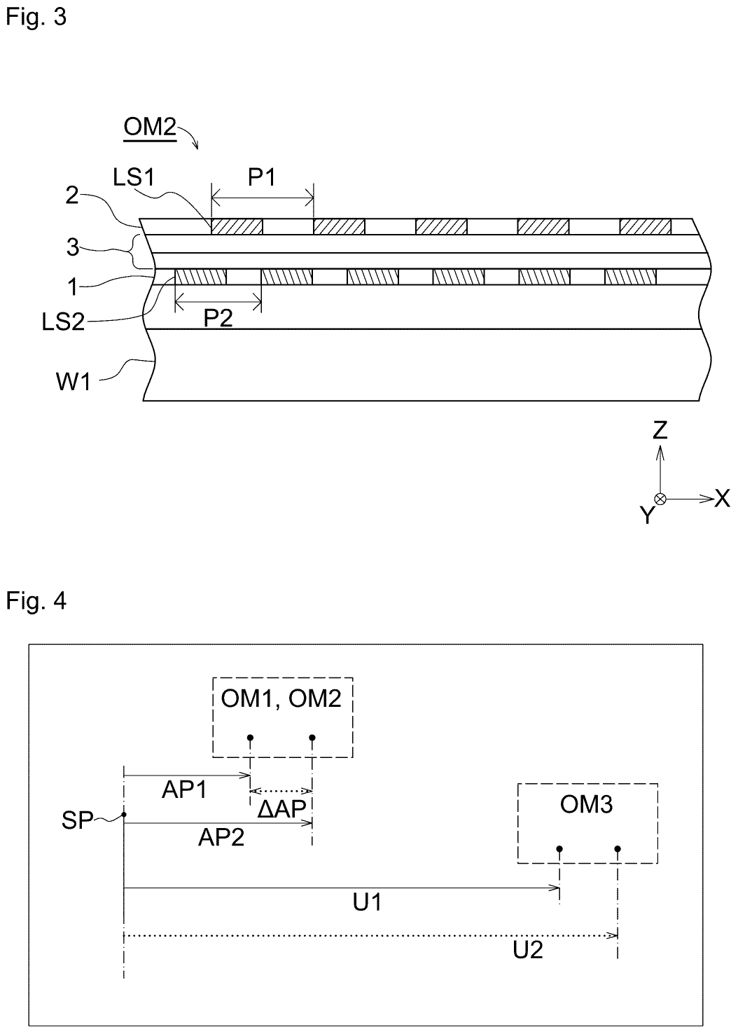

The overlay mark will be described with reference to FIGS. 1, 2, and 3. FIG. 1 is a conceptual diagram of two overlay marks (OM1, OM2) formed on a substrate W1 and the process of forming the same. FIG. 2 is a partially enlarged cross-sectional view of the first overlay mark OM1 formed in a first region on the substrate W1. FIG. 3 is a partially enlarged cross-sectional view of the second overlay mark OM2 formed in a second region on the substrate W1.

As illustrated in FIG. 1, the first overlay mark OM1 is an FBO mark formed by overlaying a second pattern LS2 on a first pattern LS1. The second overlay mark OM2 is an FBO mark formed by overlaying a first pattern LS1 on a second pattern LS2. In the first pattern LS1, a line-and-space extending in the Y direction is repeatedly formed in the X direction at a first pitch P1. In the second pattern LS2, a line-and-space extending in the Y direction is repeatedly formed in the X direction at a second pitch P2. The first pitch P1 and the second pitch P2 have different values. That is, the first overlay mark OM1 and the second overlay mark OM2 both include two patterns (LS1, LS2) having different pitches, but have a relationship that the two patterns (LS1, LS2) are formed in an order switching therebetween.

Both the first pitch P1 of the first pattern LS1 and the second pitch P2 of the second pattern LS2, constituting the overlay mark (OM1, OM2), may be 100 nm or more and 1000 nm or less, and preferably 200 nm or more and 720 nm or less.

The first region in which the first overlay mark OM1 is formed and the second region in which the second overlay mark OM2 is formed may be arranged close to each other to such an extent that the first region and the second region are included in the same visual field with a camera that images the overlay marks (OM1, OM2). Conversely, the first region and the second region may be arranged away from each other to such an extent that the first region and the second region are not included in the same visual field with a camera that images the overlay marks (OM1, OM2).

As illustrated in FIG. 2, in the first overlay mark OM1, the first pattern LS1 is formed in a first layer 1 on the substrate W1. The second pattern LS2 is formed in a second layer 2 located above the first layer 1. As illustrated in FIG. 3, in the second overlay mark OM2, the second pattern LS2 is formed in a first layer 1 on the substrate W1. The first pattern LS1 is formed in a second layer 2 located above the first layer 1. The first pattern LS1 of the first overlay mark OM1 and the second pattern LS2 of the second overlay mark OM2 are formed in the same first layer 1. The second pattern LS2 of the first overlay mark OM1 and the first pattern LS1 of the second overlay mark OM2 are formed in the same second layer 2.

Hereinafter, a pattern formed in the first layer 1 located below the second layer 2 may be referred to as “lower layer pattern”. A pattern formed in the second layer 2 located above the first layer 1 may be referred to as “upper layer pattern”.

One or two or more intermediate layers 3 may be provided between the first layer 1 and the second layer 2. The intermediate layer 3 has such a small thickness that the lower layer pattern formed in the first layer 1 can be measured by measurement light. The intermediate layer 3's such a small thickness that the lower layer pattern can be measured does not require that the lower layer pattern itself be confirmed in the image, but requires that a moire image formed by overlaying the upper layer pattern be confirmed.

The moire image will be described. When the overlay mark (OM1, OM2) is imaged, the two patterns (LS1, LS2) having different pitches interfere with each other to form a moire image in the image. Even when the first pitch P1 or the second pitch P2 is smaller than the resolution limit of an imaging unit and the imaging unit cannot recognize the first pattern LS1 or the second pattern LS2, a moire image is formed. When the pattern size of the moire image is larger than the resolution limit of the imaging unit, the overlay mark (OM1, OM2) can be measured. Of course, also when the first pitch P1 or the second pitch P2 is larger than the resolution limit of an imaging unit and the imaging unit can recognize the first pattern LS1 or the second pattern LS2, the overlay mark (OM1, OM2) can be measured.

Two or more overlay marks (OM1, OM2) are arranged in a scribe line region or the like in each shot region of the substrate W1, corresponding to each shot region. For example, 10 to 50 overlay marks (OM1, OM2) may be arranged. The overlay mark may be provided for all shots. There may be more than 1000 overlay marks on the entire wafer. When the overlay mark is measured, all the overlay marks on the substrate W1 are not necessarily measured. Alternatively, two or more overlay marks may be measured for each shot region. Furthermore, the overlay marks to be measured may be selected according to the measurement purpose. Enhanced global alignment (EGA) measurement, in which the arrangement of shot regions on the wafer is statistically calculated from the measurement result of two or more overlay marks, is preferably performed.

FIGS. 1 to 3 show, as a measurement target, an overlay mark having an upper layer pattern and a lower layer pattern in each of which a line-and-space extending in the Y direction is repeatedly formed in the X direction (hereinafter, also referred to as “overlay mark in the X direction”). However, the shape of the overlay mark, as a measurement target, is not limited thereto. The measurement target may include an overlay mark having an upper layer pattern and a lower layer pattern in each of which a line-and-space is repeatedly formed in a direction intersecting the X direction. In particular, the measurement target preferably includes an overlay mark having an upper layer pattern and a lower layer pattern repeatedly formed in the Y direction (hereinafter, also referred to as “overlay mark in the Y direction”). An overlay mark in which the overlay mark in the X direction and the overlay mark in the Y direction are arranged close to each other may be used. In this case, since the overlay mark in the X direction and the overlay mark in the Y direction arranged close to each other can be included in the same visual field, the observation position of the mark detection system MDS (described later) can be less frequently moved between the overlay marks so that the measurement time can become shorter.

The configuration and arrangement of the overlay mark can take various modes. For example, two sets of the overlay marks (OM1, OM2) may be arranged. Further, a total of four sets of overlay marks, i.e., two sets of the overlay marks in the X direction (OMx1, OMx2) and two sets of the overlay marks in the Y direction (OMy1, OMy2), may be arranged close to each other. In the case of the total of four sets of overlay marks, the total of four sets of overlay marks may be arranged close to each other, while being separated into four quadrants, where the two sets of the overlay marks in the X direction (OMx1, OMx2) are arranged point-symmetrically, and the two sets of the overlay marks in the Y direction (OMy1, OMy2) are arranged point-symmetrically with respect to the same point; or the total of four sets of overlay marks may be arranged line-symmetrically with respect to the X-axis direction or the Y-axis direction.

### [Measurement of Absolute Position of Moire Image]

Detection light is emitted from a light source to the overlay mark (OM1, OM2), and the light reflected by the overlay mark (OM1, OM2) is imaged by an imaging unit. From the image of the overlay mark (OM1, OM2), the position of the upper layer pattern and the position of the lower layer pattern are acquired. Details of the measurement device including a mark detection system that detects the overlay mark and the lithography device including an alignment detection system that detects the overlay mark will be described later.

When the positional deviation occurs between the lower layer pattern and the upper layer pattern, the position of the moire image of the overlay mark (OM1, OM2) changes. The present inventor has found that the absolute positions of the lower layer pattern and the upper layer pattern can be back-calculated from the measured absolute position of the moire image of the overlay mark (OM1, OM2). The mark measurement method using this method will be described.

First, a luminance signal is extracted from the image of the measured overlay mark (OM1, OM2). The absolute position (X1, X2) of the moire image can be obtained from the luminance signal IS. The absolute position X1 of the moire image of the first overlay mark OM1 (see FIG. 1, hereinafter, may be referred to as “first moire position X1”) is expressed as the interval between the position of the moire image of the first overlay mark OM1 and the coordinate origin SP in the X-axis direction. The absolute position X2 of the moire image of the second overlay mark OM2 (see FIG. 1, hereinafter, may be referred to as “second moire position X2”) is expressed as the interval between the position of the moire image of the second overlay mark OM2 and the coordinate origin SP in the X-axis direction. In FIG. 1, the peak point near the center of the moire image (interference fringes) of the overlay mark (OM1, OM2) (the vertex of the second central peak among the three peaks included in the interference fringes) is set as the position of the moire image of the overlay mark (OM1, OM2) in the X direction. However, the position of the moire image of the overlay mark (OM1, OM2) may be set according to other setting criteria. The coordinate origin SP can be arbitrarily set. The coordinate origin SP may be set based on the coordinate system of the measurement device or the lithography device.

The absolute position AP1 of the upper layer pattern in the X direction and the absolute position AP2 of the lower layer pattern in the X direction can be determined from the first moire position X1 and the second moire position X2. Details will be described below.

The moire image is formed by interference between the first pattern LS1 and the second pattern LS2. The first moire position X1 and the second moire position X2, each of which is the absolute position of the moire image of the overlay mark (OM1, OM2), can be expressed by the formulae (1) and (2), respectively, using the absolute position AP1 of the upper layer pattern in the X direction and the absolute position AP2 of the lower layer pattern in the X direction, and the first pitch P1 of the first pattern LS1 and the second pitch P2 of the second pattern LS2.

$$X 1 = \frac{P 2 AP 2 - P 1 AP 1}{P 2 - P 1} \qquad ( 1 )$$

$$X 2 = \frac{P 2 AP 1 - P 1 AP 2}{P 2 - P 1} \qquad ( 2 )$$

Next, the formulae (1) and (2) are solved to obtain AP1 and AP2 so that the following formulae (3) and (4) can be obtained.

$$AP 1 = \frac{P 1 X 1 + P 2 X 2}{P 1 + P 2} \qquad ( 3 )$$

$$AP 2 = \frac{P 2 X 1 + P 1 X 2}{P 1 + P 2} \qquad ( 4 )$$

The first pitch P1 of the first pattern LS1 and the second pitch P2 of the second pattern LS2 are known. Using the formulae (3) and (4), the absolute position AP1 of the upper layer pattern in the X direction and the absolute position AP2 of the lower layer pattern in the X direction can be calculated from the absolute positions of the two moire images (X1, X2).

### [Advantages of Absolute Position Measurement]

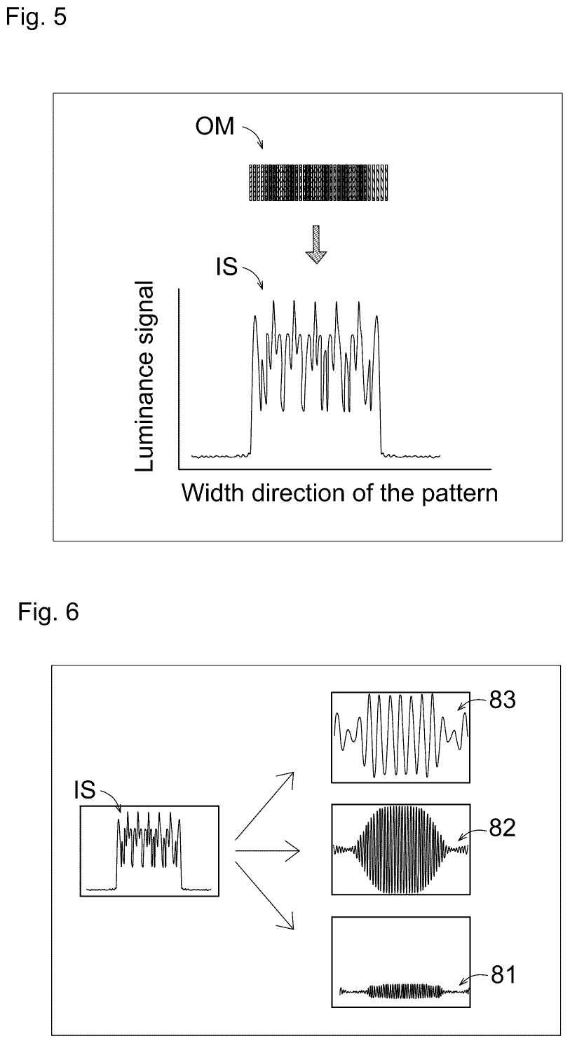

Advantages of the absolute position measurement will be described with reference to FIG. 4. When the absolute position AP1 of the upper layer pattern in the X direction and the absolute position AP2 of the lower layer pattern in the X direction are found, the difference between AP1 and AP2 can be determined to obtain the overlay relative error AAP between the upper layer pattern and the lower layer pattern. Furthermore, when the absolute position AP1 of the upper layer pattern in the X direction, the absolute position AP2 of the lower layer pattern in the X direction, and the overlay error AAP are found, for example, only the absolute position U1 of the upper layer pattern of another overlay mark OM3 is measured, and from the measurement result, the absolute position U2 of the lower layer pattern of the overlay mark OM3 can be estimated. Although not illustrated, conversely, it is also possible that the absolute position U2 of the lower layer pattern of another overlay mark OM3 is measured, and the absolute position U1 of the upper layer pattern is calculated and estimated therefrom. By estimating them, it is possible to increase the measurement speed of overlay measurement or improve the measurement accuracy. On the other hand, in the method of directly measuring the relative positions of the upper layer pattern and the lower layer pattern without measuring the absolute positions of the upper layer pattern and the lower layer pattern from the overlay mark, the position of the upper layer pattern or the lower layer pattern of another overlay mark OM3 cannot be estimated. That is, the above-described effect is an effect obtained only by measuring the absolute positions of the upper layer pattern and the lower layer pattern.

In addition, since the absolute position of the upper layer pattern and the absolute position of the lower layer pattern each can be measured, the arrangement error of two or more shot regions formed in the upper layer pattern and the arrangement error of two or more shot regions formed in the lower layer pattern can be acquired, respectively. As a result, it is possible to know which layer's positional deviation (arrangement error) causes the overlay error between the upper layer pattern and the lower layer pattern. Furthermore, when the arrangement error is fed back to one or both of the lithography device that has exposed the upper layer pattern and the lithography device that has exposed the lower layer pattern, the overlay error can be reduced.

### Second Embodiment

A second embodiment of the mark measurement method will be described. Description of the features of the second embodiment common to the first embodiment will be omitted. For example, the features related to the structure of the overlay mark are the same as those of the first embodiment, and the description of the first embodiment can be referred to.

### [Position Measurement by Separating Luminance Signal]

As a method for acquiring the position of the upper layer pattern and the position of the lower layer pattern from the image of the overlay mark (OM1, OM2), the present inventor has created a method of separating luminance signals obtained by imaging the overlay mark. Details will be described below.

FIG. 5 is a conceptual diagram illustrating that the luminance signal IS in the width direction of the pattern (the direction in which the line-and-space pattern repeats) is extracted from the image obtained by imaging the overlay mark OM. The luminance signal IS is expressed by a graph in which the horizontal axis represents the width direction of the pattern (the direction in which the line-and-space pattern repeats) and the vertical axis represents the luminance (intensity) of the signal obtained from the image.

The separation of the luminance signal will be described with reference to FIG. 6. The luminance signal IS illustrated on the left side of FIG. 6 is obtained by imaging the overlay mark OM as illustrated in FIG. 5. The luminance signal IS includes a component of reflected light from the upper layer pattern, a component of reflected light from the lower layer pattern, and a component of interference light between the upper layer pattern and the lower layer pattern (that is, light constituting the moire image). Since each of these components has a unique frequency, the luminance signal IS can be frequency-resolved. FIG. 6 illustrates that the luminance signal IS is frequency-resolved to extract a signal component 82 of reflected light from the upper layer pattern, a signal component 81 of reflected light from the lower layer pattern, and a signal component 83 of interference light between the upper layer pattern and the lower layer pattern, respectively.

By detecting the phase of the extracted signal component 82 of reflected light from the upper layer pattern, the absolute position AP1 of the upper layer pattern in the X direction can be determined. Similarly, by detecting the phase of the signal component 81 from the lower layer pattern, the absolute position AP2 of the lower layer pattern in the X direction can be determined. Advantages of determining the absolute positions (AP1, AP2) of the upper layer pattern and the lower layer pattern are as described in the first embodiment.

### [Separation of Luminance Signal Using Inner Product Method]

Conventionally, as a method for extracting a specific frequency component from a luminance signal including two or more frequencies, a method using discrete Fourier transform (hereinafter, may be referred to as “DET”) is known. DFT can be applied to the separation of the luminance signal IS described above. However, when the absolute positions of the upper layer pattern and the lower layer pattern are determined using DFT, the separated signals of the upper layer pattern and the lower layer pattern include a large phase error. Therefore, the error of the detection position is increased. According to the analysis by the present inventors, this is partially because the signal to which DFT is applied is assumed to have an infinite length, but the actual luminance signal IS has a finite length.

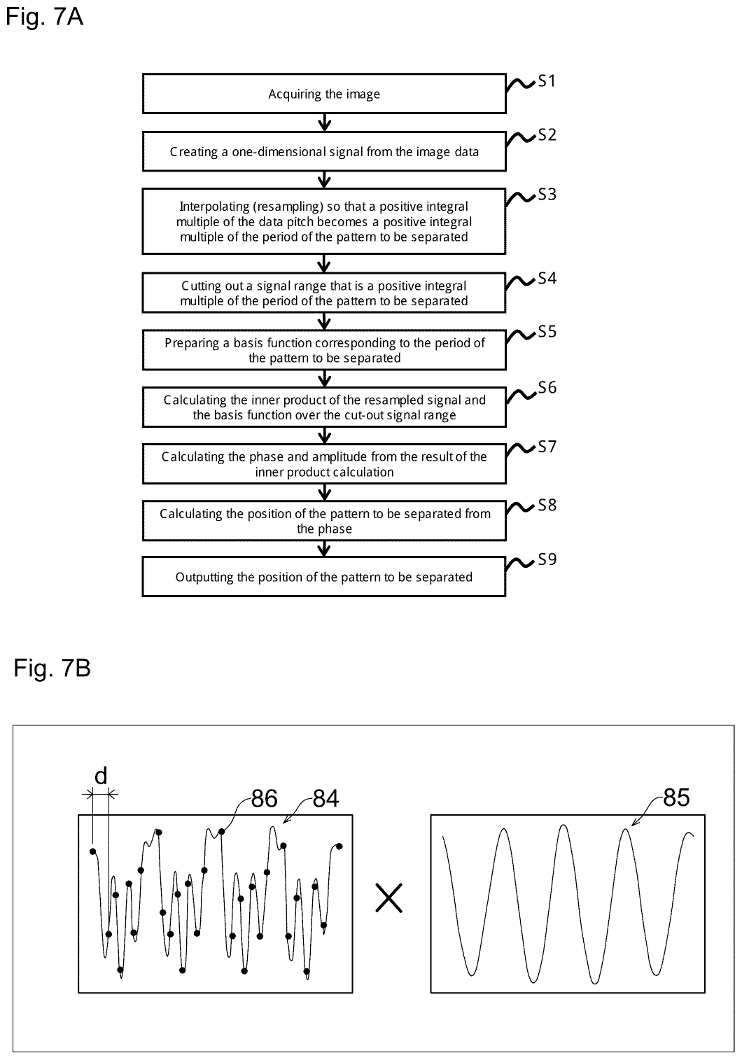

Therefore, the present inventors have created a method of separating the signal of a pattern to be separated from the luminance signal IS by extracting a specific frequency component from the actual luminance signal IS. The method will be specifically described with reference to FIGS. 7A and 7B. FIG. 7A is a flowchart showing a method for extracting the frequency component of a pattern to be extracted from the luminance signal IS. The left side of FIG. 7B is an example of the luminance signal IS acquired from the image, and the right side is an example of the basis function of the signal to be extracted.

An example of the method will be described with reference to FIG. 7A. First, an image of the overlay mark is acquired (step S1). Next, a one-dimensional luminance signal IS along a predetermined direction (for example, the X direction) is created from the image data (step S2). Next, the luminance signal is resampled such that a positive integral multiple of a data pitch d is equal to a positive integral multiple of the period of the pattern to be separated (step S3). At this time, the data pitch d is set such that the data pitch d is smaller than half of the period of the pattern to be separated. Next, the luminance signal IS is cut out to be positive integer times the period of the pattern to be separated (step S4). In parallel with these processes, or in advance, a basis function corresponding to the period of the pattern to be separated is prepared (step S5).

Here, in FIG. 7B, the left signal 84 indicates a finite length signal obtained by cutting out a signal length that is positive integer times the period of the pattern to be extracted from the luminance signal IS. The signal 84 includes a plurality of resampling points 86 resampled at the data pitch d. In the example of FIG. 7B, there are 29 resampling points 86. Thus, the signal 84 has a length that is 28 times (positive integer times) the data pitch d. In FIG. 7B, the right graph 85 is a basis function of the frequency to be extracted. As the basis function, a sine function having a length that is positive integer times the period of the frequency to be extracted can be used. In FIG. 7B, a sine function having four periods is illustrated as the basis function. That is, 28 multiple (positive integral multiple) of the data pitch d is four periods (positive integral multiple of one period) of the basis function, and the signal 84 is a signal cut out from the luminance signal IS to be four periods (positive integral multiple) of the basis function.

Next, the inner product of the signal 84 and the basis function shown in the graph 85 is calculated in a range of the cut-out signal (step S6). As a result, the frequency component to be extracted can be more accurately extracted from the signal 84 having a finite length. Thereafter, the phase and the amplitude are calculated from the calculated inner product (step S7). Next, the position of the pattern to be separated is calculated from the calculated phase (step S8). As a result of the calculation, the position of the pattern is output (step S9). By calculating the phase of the extracted frequency component in this manner, the position of the pattern to be separated (the absolute position of the upper layer pattern or the lower layer pattern) can be determined more accurately.

This signal separation method may be referred to as signal separation using the inner product method. The signal separation using the inner product method makes it possible to calculate the position of the pattern more accurately than the signal separation using DFT. Note that the basis function of the frequency to be extracted is preferably selected so that the basis function is orthogonal to the function of the frequency to be excluded (that is, the frequency other than the frequency to be extracted and the noise component). By selecting the basis function in this way, the influence of the frequency to be excluded can be eliminated. When the signal 84 can be cut out from the luminance signal IS at a positive integral multiple of the period of the pitch of the pattern to be separated, resampling (complementation) is not necessary.

It has been described above that the absolute position AP1 of the upper layer pattern in the X direction and the absolute position AP2 of the lower layer pattern in the X direction can be determined from the luminance signal IS. In addition, the signal component 83 of interference light between the upper layer pattern and the lower layer pattern (that is, light constituting the moire image) may be separated from the luminance signal IS to detect the absolute position of the moire image in the X direction from the signal component 83. Specifically, a luminance signal is resampled from the luminance signal IS so that a signal length that is positive integer times the pitch of the moire image can be cut out, and then the inner product between the resampled luminance and the basis function of the frequency of the moire image signal is determined. Consequently, the frequency component of the moire image signal is extracted, and the phase of the extracted frequency component is detected, so that the absolute position of the moire image can be determined from the phase. Separating the moire image signal from the luminance signal IS to detect the absolute position of the moire image is not an essential step in the second embodiment. However, when the absolute position of the moire image can be detected, the absolute position AP1 of the upper layer pattern in the X direction and the absolute position AP2 of the lower layer pattern in the X direction can be determined using the formulae (1) to (4) as described in the first embodiment.

The signal separation using the inner product method, a method for accurately separating the luminance signal IS, may be used, not only to determine the absolute position of the upper layer pattern or the lower layer pattern from the signal component after component separation, but also to determine the relative positions of the upper layer pattern and the lower layer pattern. That is, the luminance signal separation using the inner product method can be used not only in absolute position measurement but also in relative position measurement.

### Third Embodiment

### [Another Embodiment of Overlay Mark]

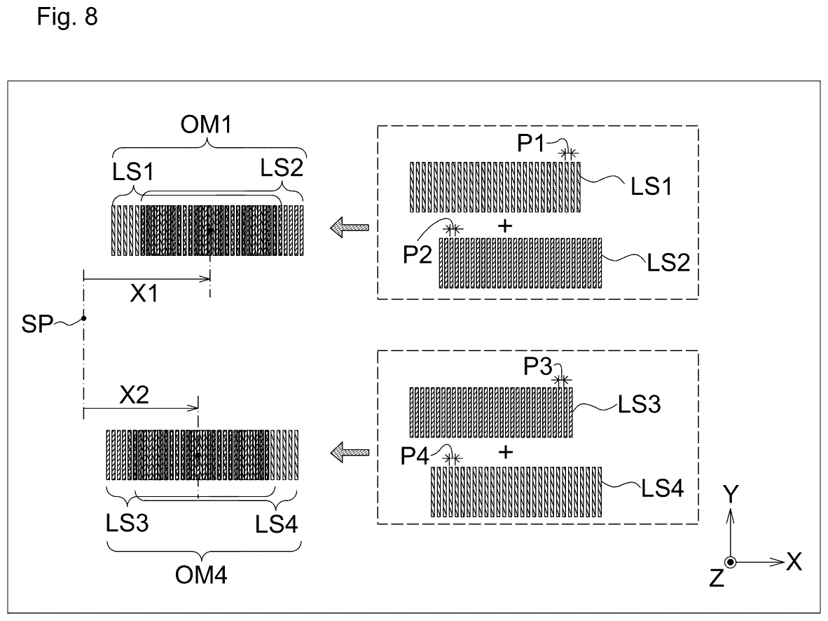

A third embodiment of the mark measurement method will be described. The features of the overlay mark to be measured will be described with reference to FIGS. 8, 9, and 10. Description of the features of the third embodiment common to the first and second embodiments will be omitted. For example, regarding the measurement method of the overlay mark, the descriptions of the first and second embodiments may be referred to for the parts not described below.

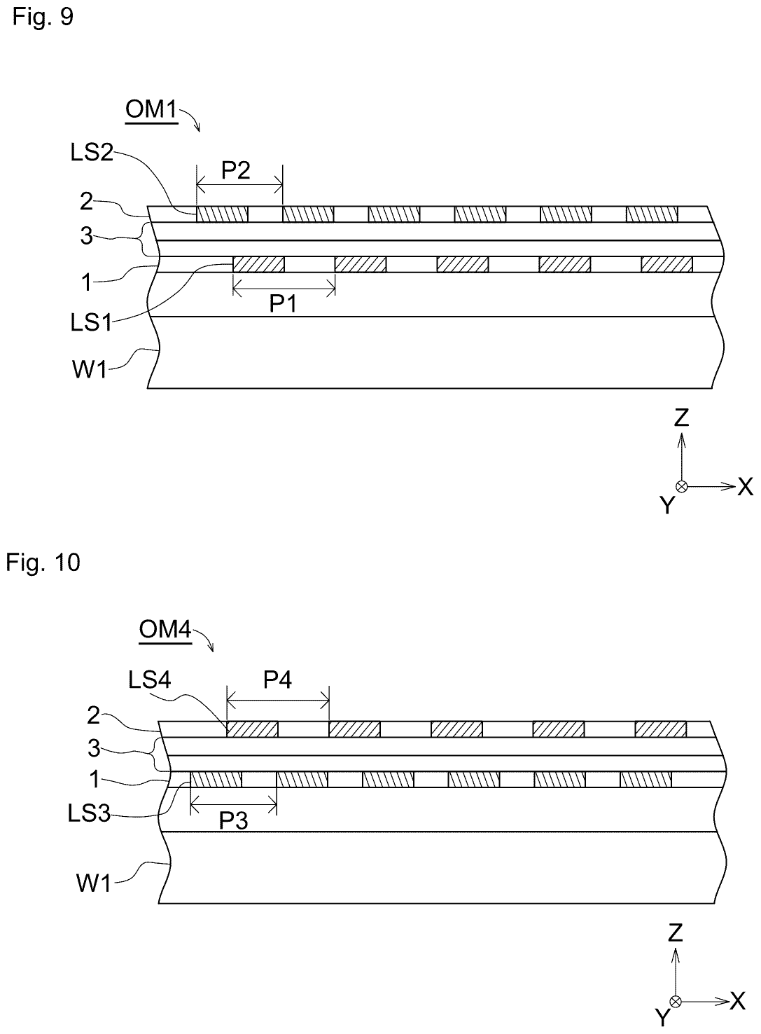

FIG. 8 is a conceptual diagram of two overlay marks (OM1, OM4) formed on a substrate W1 and the process of forming the same. FIG. 9 is a partially enlarged cross-sectional view of the first overlay mark OM1 formed in a first region on the substrate W1. FIG. 10 is a partially enlarged cross-sectional view of the fourth overlay mark OM4 formed in a second region on the substrate W1.

As illustrated in FIG. 8, the first overlay mark OM1 is an FBO mark formed by overlaying a second pattern LS2 on a first pattern LS1. The fourth overlay mark OM4 is an FBO mark formed by overlaying a fourth pattern LS4 on a third pattern LS3. In the first pattern LS1, a line-and-space extending in the Y direction is repeatedly formed in the X direction at a first pitch P1. In the second pattern LS2, a line-and-space extending in the Y direction is repeatedly formed in the X direction at a second pitch P2. In the third pattern LS3, a line-and-space extending in the Y direction is repeatedly formed in the X direction at a third pitch P3. In the fourth pattern LS4, a line-and-space extending in the Y direction is repeatedly formed in the X direction at a fourth pitch P4. The first pitch P1 and the second pitch P2 have different values. The third pitch P3 and the fourth pitch P4 have different values.

The overlay mark disclosed in the third embodiment is different from the overlay mark disclosed in the first embodiment in that the first pitch P1 and the fourth pitch P4 have different values, and the second pitch P2 and the third pitch P3 have different values. That is, as illustrated in FIG. 9, the first overlay mark OM1 has the first pattern LS1 as the lower layer pattern, and the second pattern LS2 as the upper layer pattern. On the other hand, as illustrated in FIG. 10, the fourth overlay mark OM4 has the third pattern LS3 as the lower layer pattern, and the fourth pattern LS4 as the upper layer pattern, instead of the embodiment that the two patterns (LS1, LS2) are formed in an order switching therebetween, as illustrated in FIG. 9.

Also in the configuration that the two overlay marks (OM1, OM4) are configured by the four patterns (LS1 to LS4) as described above, the absolute position of the moire image can be measured. Note that the overlay mark in which the first pitch P1 and the fourth pitch P4 have the same value, and the second pitch P2 and the third pitch P3 have the same value corresponds to an overlay mark having a relationship that the two patterns (LS1, LS2) are formed in an order switching therebetween as described in the first embodiment, and naturally, the absolute position of the moire image can be measured.

A method for determining the absolute position AP1 of the upper layer pattern in the X direction and the absolute position AP2 of the lower layer pattern in the X direction from the first moire position X1 of the overlay mark OM1 and the second moire position X2 of the overlay mark OM4 will be described.

First, the first moire position X1 and the second moire position X2, which are absolute positions of the moire images in the overlay marks (OM1, OM4), have been formulated. These moire positions (X1, X2) can be expressed by the formulae (5) and (6), respectively, using the absolute position AP1 of the upper layer pattern in the X direction and the absolute position AP2 of the lower layer pattern in the X direction, and the first pitch P1 of the first pattern LS1, the second pitch P2 of the second pattern LS2, the third pitch P3 of the third pattern LS3, and the fourth pitch P4 of the fourth pattern LS4.

$$X 1 = \frac{P 2 AP 2 - P 1 AP 1}{P 2 - P 1} \qquad ( 5 )$$

$$X 2 = \frac{P 3 AP 1 - P 4 AP 2}{P 3 - P 4} \qquad ( 6 )$$

Next, the formulae (5) and (6) are solved to obtain AP1 and AP2 so that the following formulae (7) and (8) can be obtained.

$$AP 1 = \frac{P 4 ( P 2 - P 1 ) X 1 + P 2 ( P 3 - P 4 ) X 2}{P 2 P 3 - P 1 P 4} \qquad ( 7 )$$

$$AP 2 = \frac{P 3 ( P 2 - P 1 ) X 1 + P 1 ( P 3 - P 4 ) X 2}{P 2 P 3 - P 1 P 4} \qquad ( 8 )$$

The first pitch P1 of the first pattern LS1, the second pitch P2 of the second pattern LS2, the third pitch P3 of the third pattern LS3, and the fourth pitch P4 of the fourth pattern LS4 are known. Using the formulae (7) and (8), the absolute position AP1 of the upper layer pattern in the X direction and the absolute position AP2 of the lower layer pattern in the X direction can be calculated from the absolute positions of the two moire images (X1, X2).

The three embodiments of the mark measurement method have been described above. The mark measurement method can be incorporated into the measurement device as described below or the lithography device as described below to measure the overlay mark. Details of the measurement device and the lithography device will be described later. In addition, the mark measurement method described above may be used to measure an overlay mark formed on a reference substrate as described below. Details will be described below.

### <Use of Reference Substrate>

When a substrate is attracted to a substrate holder, the substrate may be deformed. In particular, there is a difference in deformation mode and deformation amount of the substrate between different substrate holders. The difference in deformation mode and deformation amount of the substrate affects the measurement result of the overlay mark. The overlay measurement device and the lithography device including an overlay measurement device mounted therein have a unique substrate holder. Therefore, even when the same substrate is measured, the measurement result may differ between different measurement devices, between a measurement device and a lithography device, and between lithography devices. Furthermore, even when the same substrate is measured with the same device, the deformation mode and the deformation amount of the substrate may differ every time the substrate is attracted to the substrate holder so that the measurement result differs.

The overlay measurement may be used for measurement performance matching between two or more measurement devices or between two or more lithography devices, or may be used for regular calibration on measurement accuracy of a measurement device or a lithography device. The overlay measurement error caused due to a difference in the substrate holder or a difference in the timing of placing the substrate may deteriorate the inspection result, the accuracy of measurement performance matching, and accuracy of calibration. Therefore, the substrate used when overlay measurement is performed for the purpose described above is preferably a highly accurate substrate that hardly affects the measurement result. Preferable examples of the highly accurate substrate to be used include a reference substrate that is less likely to be distorted than a substrate for product manufacturing even when attracted to a substrate holder.

The reference substrate to be used is preferably a reference wafer having an outer shape similar to that of a wafer for product manufacturing. When the reference wafer is used, the deformation amount of the substrate is suppressed when the substrate is attracted to a substrate holder as compared with a wafer for product manufacturing (for example, a silicon single crystal wafer). Further, the reproducibility of the deformation amount of the reference wafer is higher than that of a wafer for product manufacturing. Therefore, by using the reference wafer, it is possible to eliminate an error caused by substrate deformation in overlay measurement for matching between measurement devices or between lithography devices, or in regular overlay measurement on measurement accuracy of a measurement device or a lithography device. Thereby, the measurement accuracy of the measurement device, the measurement accuracy of the lithography device, and the overlay accuracy can be improved.

The reference wafer has a structure different from that of the silicon single crystal wafer to be used for product manufacturing. The reference wafer may have a multilayer structure instead of a single layer structure. Here, a reference wafer having a three-layer structure capable of overlay measurement with high accuracy will be particularly described.

The reference wafer having a three-layer structure has a central layer located at the center in the thickness direction and two layers sandwiching the central layer. The central layer and the two layers can provide a wafer with predetermined functions. Therefore, the reference wafer having a three-layer structure is easy to design to improve measurement accuracy. In addition, when the two layers sandwiching the central layer are made of the same material, the thermal expansion coefficients can become equal on both sides to design a wafer with small deformation due to temperature change. Hereinafter, an example of the reference wafer having a three-layer structure will be described.

### [First Reference Wafer]

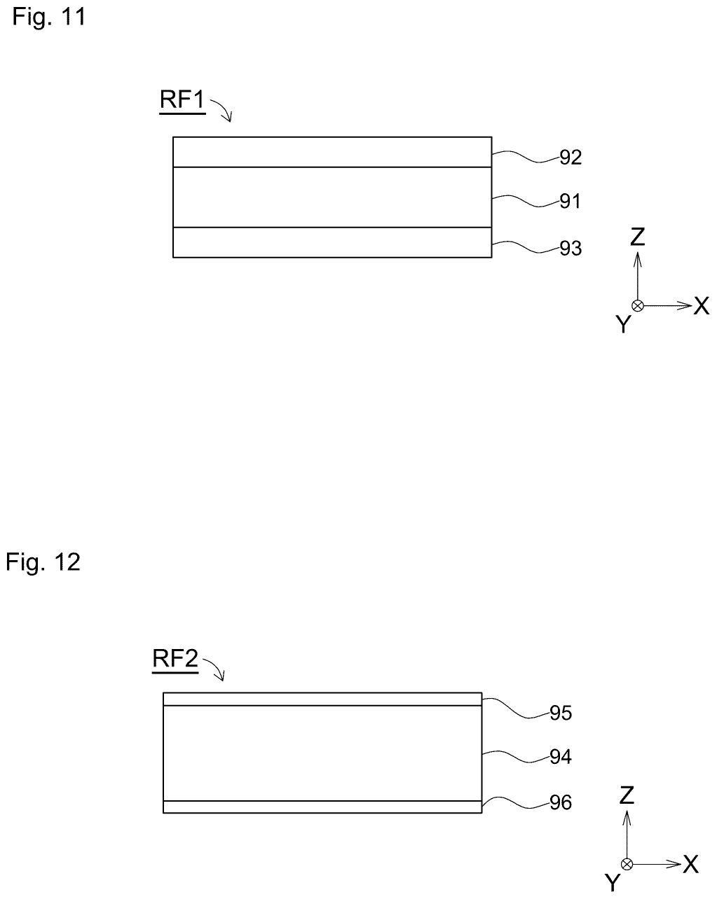

FIG. 11 illustrates a cross-sectional view of a first reference wafer RF1. The first reference wafer RF1 includes a base material 91 made of silicon single crystal, a first layer 92 provided on one surface of the base material 91, and a second layer 93 provided on another surface of the base material 91. For example, SiC (silicon carbide) is used as the first layer 92 and the second layer 93. The hardness of SiC is higher than the hardness of the base material 91 made of silicon single crystal. The first reference wafer RF1 is a wafer resistant to distortion because the hardness of the surface is higher than the hardness of the inside.

The first layer 92 and the second layer 93 may be made of substantially the same material. The first layer 92 and the second layer 93 may be designed to have substantially the same thickness. However, the first layer 92 and the second layer 93 are not limited to these conditions. For example, the first layer 92 and the second layer 93 may be intentionally made of different materials, or the first layer 92 and the second layer 93 may be intentionally made to have different thicknesses. The thickness of each of the first layer 92 and the second layer 93 may be thicker than the thickness of the base material 91.

### [Second Reference Wafer]

FIG. 12 illustrates a second reference wafer RF2. The second reference wafer RF2 includes a base material 94 made of nonmetallic material, a first layer 95 provided on one surface of the base material 94, and a second layer 96 provided on another surface of the base material 94. For example, ceramic is used as the base material. Ceramic has high hardness and is resistant to distortion. Therefore, the second reference wafer RF2 is a wafer more resistant to distortion than a silicon single crystal wafer for product manufacturing. In addition, ceramic has advantages such as having high chemical resistance and being capable of cleaning with hydrofluoric acid, and having high heat resistance. As the ceramic, for example, polycrystalline alumina is used. The polycrystalline alumina, having a high Young's modulus, has physical properties close to sapphire, and is suitable for the base material.

The first layer 95 and the second layer 96 may have a slight thickness that can be referred to as a film, for example, a thickness of less than 1 μm. The first layer 95 and the second layer 96 preferably have a thickness of less than 600 nm. The first layer 95 and the second layer 96 are preferably made of, for example, silicon. When a silicon film is formed on the surface of the base material 94, the silicon film can be polished by CMP or the like, so that the surface of the second reference wafer RF2 is as rough as the surface of a wafer for product manufacturing. The surface roughness Ra of the second reference wafer RF2 on the side where the pattern is formed is, for example, preferably 5 nm or less, and preferably 1 nm or less. In addition, since the first layer 95 and the second layer 96 function as a protective layer for preventing metal contamination, metal contamination can be reduced by using the second reference wafer RF2.

Although the first layer 95 and the second layer 96 are made of substantially the same material as described above, the first layer 95 and the second layer 96 may be intentionally made of different materials. The first layer 95 and the second layer 96 may be designed to have substantially the same thickness, or the first layer 95 and the second layer 96 may be intentionally made to have different thicknesses.

### [Third Reference Wafer]

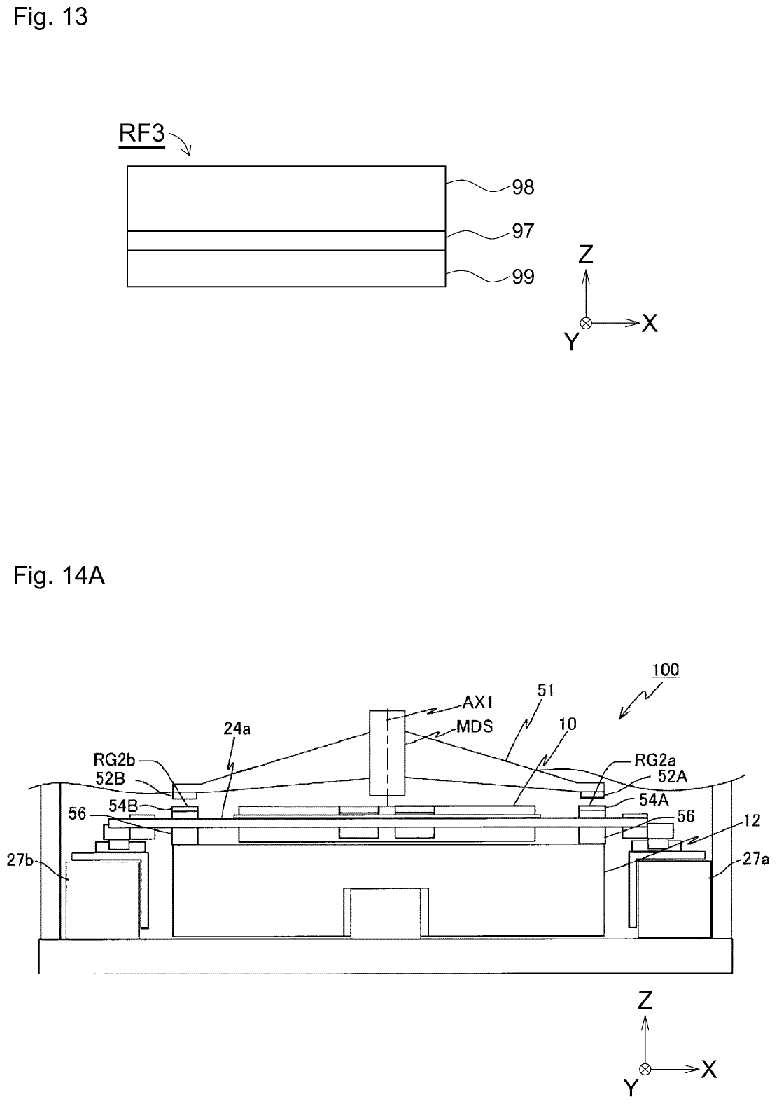

FIG. 13 illustrates a third reference wafer RF3. The third reference wafer RF3 includes a central layer 97 made of resin or the like, a first layer 98 provided on one surface of the central layer 97, and a second layer 99 provided on another surface of the central layer 97. The central layer 97 is made of, for example, polyimide. Polyimide is excellent as a reference wafer in terms of heat resistance, chemical resistance, and Young's modulus.

Unlike the first reference wafer RF1 and the second reference wafer RF2, the third reference wafer RF3 has the central layer 97 made of a relatively soft material having hardness lower than that of the first layer 98 and the second layer 99. Therefore, the third reference wafer RF3 is difficult to diffuse a locally generated distortion and transmit the distortion. As a result, the third reference wafer RF3 can suppress distortion as a whole as compared with a silicon single crystal wafer for product manufacturing.

The resin used for the central layer 97 may be a material used as an adhesive for bonding the first layer 98 and the second layer 99. The resin used for the central layer 97 may be a thermosetting resin or a photocurable resin.

For example, a silicon single crystal material is used for the first layer 98 and the second layer 99. Since the surface is a silicon single crystal material, the same surface as a wafer for product manufacturing can be formed. Since the silicon single crystal material can be easily polished, it is possible that the first layer 98 and the second layer 99 are polished so that the third reference wafer RF3 is as thick as a wafer for product manufacturing.

In the third reference wafer RF3 illustrated in FIG. 13, the thickness of the central layer 97 is preferably thinner than the thickness of each of the first layer 98 and the second layer 99. The thickness of the second layer 99 may be, for example, 50 μm or less, preferably 30 μm or less, and may be, for example, 5 μm or more, preferably 10 μm or more. The thickness of the first layer 98 is preferably larger than the thickness of the second layer 99. The thickness of the first layer 98 may be 300 μm or more, and preferably 500 μm or more. The thickness of the second layer 99 may be 200 μm or less, and preferably 150 μm or less. The first layer 98 and the second layer 99 may be made of substantially the same material, or the first layer 98 and the second layer 99 may be intentionally made of different materials.

### <Measurement Device>

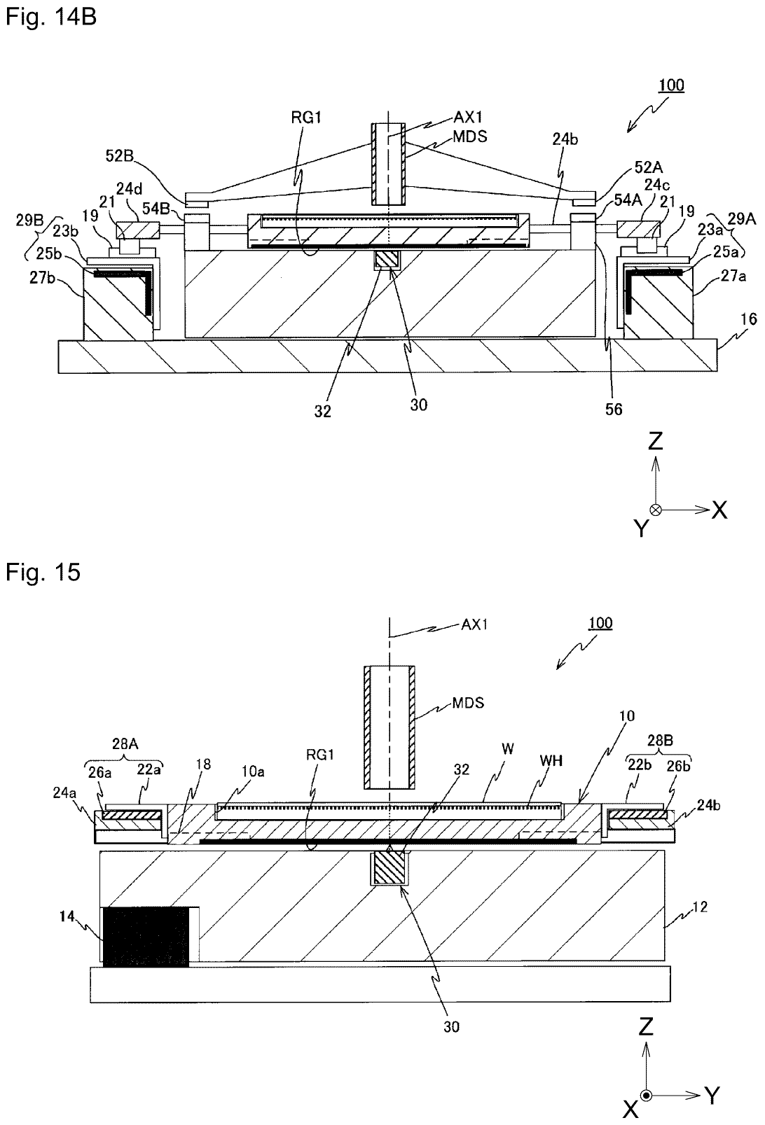

An example of the measurement device for measuring the overlay mark described above will be illustrated. FIG. 14A is a partially omitted front view of a measurement device 100 (a view seen from the −Y direction). FIG. 14B is a partially omitted cross-sectional view of the measurement device 100 that is taken along the XZ plane passing through the optical axis AX1 of the mark detection system MDS as described below. FIG. 15 is a partially omitted cross-sectional view of the measurement device 100 that is taken along the YZ plane passing through the optical axis AX1. Note that the measurement device 100 illustrated in FIGS. 14A, 14B, and 15 is housed in a housing (not illustrated).

The measurement device 100 includes a mark detection system MDS for detecting the overlay mark OM described above. Hereinafter, the direction of the optical axis AX1 of the mark detection system MDS is defined as the Z-axis direction. The direction in which the movable stage described below moves with a long stroke in a plane orthogonal to the Z axis is defined as the Y-axis direction. The direction orthogonal to the Z axis and the Y axis is defined as the X-axis direction. The rotation (inclination) directions around the X axis, the Y axis, and the Z axis are defined as the ex, θy, and θz directions, respectively. The mark detection system MDS has an L-shaped outer shape in a side view (for example, as seen from the +X direction). The mark detection system MDS includes a cylindrical lens barrel at the lower end (tip) of the mark detection system MDS. The lens barrel houses an optical system including two or more lens elements having the optical axis AX1 in the Z-axis direction (for example, refractive optical system). In the present specification, the optical axis AX1 of the optical system housed inside the lens barrel is referred to as the optical axis AX1 of the mark detection system MDS.

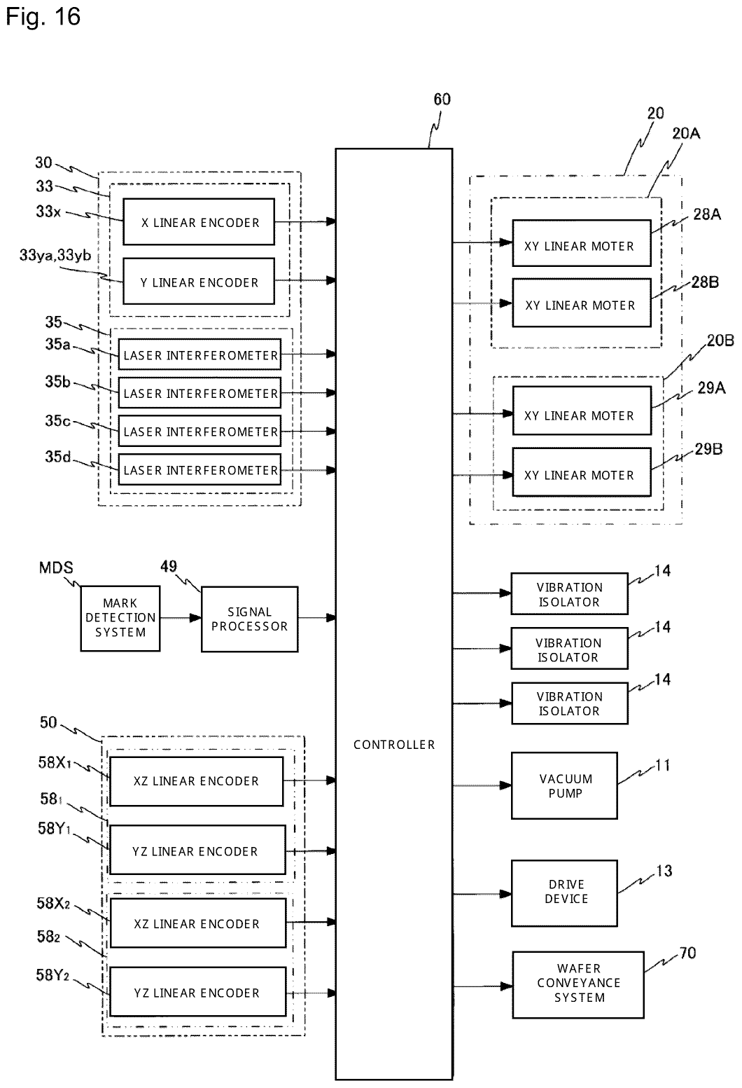

The measurement device 100 includes a surface plate 12 (see FIG. 14A); a wafer slider 10 that is arranged on the surface plate 12 and capable of minutely moving while holding a wafer W (hereinafter, may be abbreviated as “slider 10”, see FIG. 14A); a drive system 20 that drives the slider 10 (not illustrated in FIG. 14A, see FIG. 16); a first position measurement system 30 that measures the position information of the slider 10 with respect to the surface plate 12 (not illustrated in FIG. 14A, see FIGS. 14B, 15, and 16); a mark detection system MDS that detects a mark on the wafer W mounted (or held) on the slider 10; a second position measurement system 50 that measures the relative position information between the mark detection system MDS and the surface plate 12 (not illustrated in FIG. 14A, see FIG. 16); and a controller 60 (not illustrated in FIG. 14A, see FIG. 16). The wafer W includes the reference substrate and the substrate for product manufacturing described above.

The surface plate 12 has an upper surface substantially parallel to the XY plane orthogonal to the optical axis AX1. The slider 10 can move with a predetermined stroke in the X-axis and Y-axis directions with respect to the surface plate 12, and can minutely move (minutely displace) in the Z-axis, θx, θy, and θz directions. The first position measurement system 30 measures the position information of the slider 10 with respect to the surface plate 12 in each of the X-axis, Y-axis, Z-axis, θx, θy, and θz directions (hereinafter, referred to as “six-degree-of-freedom directions”). Optionally, the controller 60 controls the driving of the slider 10 by a drive system 20, acquires the measurement information by the first position measurement system 30 and the measurement information by the second position measurement system 50, and obtains the position information of two or more marks on the wafer W held on the slider 10 using the mark detection system MDS.

More specifically, the surface plate 12 has a rectangular (or square) shape in plan view. The upper surface of the surface plate 12 is finished to have very high flatness, and has a guide surface formed thereon to help the slider 10 move. As the material of the surface plate 12, a material having a low thermal expansion coefficient that is also called zero-expansion material is used, examples of which include an invar type alloy, ultra-low expansion cast steel, or ultra-low expansion glass ceramics.

The surface plate 12 has a space formed therein, and a vibration isolator 14 may be arranged in the space (see FIG. 15). Two or more vibration isolators 14 may be provided. Although not shown in the drawing, the surface plate 12 has three spaces, and three vibration isolators 14 are arranged in the spaces, respectively. The surface plate 12 is supported by the three vibration isolators 14. The surface plate 12 is supported at three points on the upper surface of a base frame 16 installed on the floor, the upper surface being parallel to the XY plane, so that the upper surface of the surface plate 12 is substantially parallel to the XY plane. Note that the number of vibration isolators 14 is not limited to three.

The vibration isolator 14 may constitute at least a part of an active vibration isolation system (also referred to as “AVIS”). The vibration isolator 14 may selectively include an accelerometer, a displacement sensor (for example, a capacitance sensor), an actuator (for example, a voice coil motor), an air mount that functions as an air damper, and the like. The air mount has a high internal pressure of gas within its gas chamber, and is difficult to secure control response (for example, up to about 20 Hz). Therefore, when the vibration isolator 14 includes both an actuator and an air mount, high control response can be achieved by controlling the actuator. In addition, when the actuator is controlled according to the output of the accelerometer (not illustrated), further high control response can be achieved. Fine vibrations, such as floor vibrations, may be removed by the air mount. The vibration isolator 14 can avoid transmission of vibrations between the surface plate 12 and the base frame 16 (see FIG. 14B). Instead of the air mount, a hydraulic damper may be used.

The upper end surface of the vibration isolator 14 is connected to the surface plate 12. The air mount can be supplied with a gas (for example, compressed air) through a gas supply port (not illustrated). The air mount expands and contracts with a predetermined stroke (for example, about 1 mm) in the Z-axis direction according to the amount of gas filled therein (pressure change of compressed air). Therefore, by using the air mounts included in each of the three vibration isolators 14, each of the three points of the surface plate 12 separately moves up and down from below, so that the surface plate 12 and the slider 10 floated and supported thereon can be arbitrarily adjusted in the position of each of the Z-axis direction, the θx direction, and the θy direction.

The actuator of the vibration isolator 14 can drive the surface plate 12 not only in the Z-axis direction but also in the X-axis direction and the Y-axis direction. The driving amount in the X-axis direction and the Y-axis direction is smaller than the driving amount in the Z-axis direction.

The three vibration isolators 14 are connected to the controller 60 (see FIG. 16). Each of the three vibration isolators 14 may have an actuator that can move the surface plate 12 not only in the X-axis direction, in the Y-axis direction, and in the Z-axis direction, but in the six-degree-of-freedom directions, for example. The controller 60 controls the actuators of the three vibration isolators 14 in real time at all times. The control is preferably performed based on the relative position information between the mark detection system MDS and the surface plate 12 measured by the second position measurement system 50. The control may be performed such that the surface plate 12 to which a head 32 of the first position measurement system 30 (see FIGS. 14B and 15) is fixed is kept in a predetermined positional relationship with respect to the mark detection system MDS in the position of six-degree-of-freedom directions. Each of the three vibration isolators 14 may be feedforward-controlled. For example, the controller 60 may perform feedforward control on each of the three vibration isolators 14 based on measurement information of the first position measurement system 30.

As illustrated in FIG. 15, the slider 10 is attached with four bearings 18. In the embodiment, an air static pressure bearing (air bearing) is adopted as the bearing 18. The bearing 18 is attached to each of the four corners of the lower surface of the slider 10 one by one. The bearing 18 is attached so that the bearing surface of each bearing 18 is substantially flush with the lower surface of the slider 10. Pressurized air is ejected from the four bearings 18 toward the surface plate 12. Then, the slider 10 floats from the surface plate 12 by the static pressure (pressure in the gap) of pressurized air between the bearing surface and the upper surface (guide surface) of the surface plate 12. The clearance (space, gap) between the lower surface of the slider 10 and the upper surface of the surface plate 12 may be, for example, 10 μm or less, and preferably 5 μm or less. In the embodiment, as the material of the slider 10, a zero-expansion glass (for example, ZERODUR from SCHOTT), which is a kind of the zero-expansion material, is used.

The slider 10 has a recess 10a formed thereon. The recess 10a has an inner diameter larger than the diameter of the wafer W. The recess 10a has a substantially circular shape in plan view. A wafer holder WH having substantially the same diameter as the diameter of the wafer W is arranged inside the recess 10a. As the wafer holder WH, a vacuum chuck, an electrostatic chuck, a mechanical chuck, or the like can be used. For example, a pin chuck type vacuum chuck may be used. The wafer W is attracted and held by the wafer holder WH such that the upper surface of the wafer W is substantially flush with the upper surface of the slider 10. The wafer holder WH includes two or more suction ports. The two or more suction ports are connected to a vacuum pump 11 via a vacuum piping system (not illustrated) (see FIG. 16). The controller 60 controls the vacuum pump 11 for on/off of operation, operation output, and the like.

The slider 10 includes a vertical moving pin (not illustrated) that vertically moves the wafer W on the wafer holder WH. When the wafer W is unloaded from the wafer holder WH, the vertical moving pin is raised to lift the wafer W from the wafer holder WH. As a result, the arm of a wafer conveyance system 70 easily holds the wafer. When the wafer W is attracted to the wafer holder WH, the vertical moving pin is lowered to bring the lower surface of the wafer W into close contact with the wafer holder WH. The vertical moving pin is vertically moved by a driver 13 controlled by the controller 60 (see FIG. 16).

For example, the wafer holder WH preferably attracts and holds a wafer having a diameter of 300 mm. When the wafer conveyance system 70 includes a non-contact holding member (for example, Bernoulli chuck) that attracts and holds the wafer on the wafer holder WH from above in a non-contact manner, the slider 10 may have no vertical moving pin.

As illustrated in FIGS. 14B and 15, a two-dimensional grating (hereinafter, simply referred to as grating) RG1 is arranged horizontally (parallel to the surface of the wafer W) in a region slightly larger than the wafer W in the lower surface of the slider 10. The grating RG1 includes a reflection type diffraction grating (X diffraction grating) having a periodic direction in the X-axis direction and a reflection type diffraction grating (Y diffraction grating) having a periodic direction in the Y-axis direction. The pitch of the grating lines of the X diffraction grating and the Y diffraction grating is, for example, 1 μm.

As illustrated in FIG. 16, the drive system 20 includes a first drive device 20A and a second drive device 20B. The first drive device 20A includes XY linear motors (28A, 28B). The second drive device 20B includes XY linear motors (29A, 29B). The first drive device 20A drives the slider 10 in the X-axis direction. The second drive device 20B drives the slider 10 in the Y-axis direction together with the first drive device 20A.

As illustrated in FIG. 15, a pair of movers 22a including a magnet unit (or a coil unit) is provided on the side surface on the −Y side of the slider 10. The pair of movers 22a has an inverted L shape in side view, and is fixed at a predetermined interval in the X-axis direction. As illustrated in FIG. 15, a pair of movers 22b including a magnet unit (or a coil unit) is provided on the side surface on the +Y side of the slider 10. The pair of movers 22b is fixed at a predetermined interval in the X-axis direction. The pair of movers 22a and the pair of movers 22b are arranged symmetrically. The movers 22a and 22b are supported in a non-contact manner on the upper surfaces of a pair of plate members 24a and 24b extending in the X-axis direction, the upper surfaces being substantially parallel to the XY plane.

As illustrated in FIG. 15, on the upper surfaces of the pair of plate members 24a and 24b, stators 26a and 26b each including a coil unit (or a magnet unit) are arranged in the region excluding both ends in the X-axis direction. The electromagnetic interaction between the pair of movers 22a and the stator 26a generates driving forces (electromagnetic forces) for driving the pair of movers 22a in the X-axis direction and the Y-axis direction.

The pair of movers 22a and the stator 26a constitute the XY linear motor 28A that generates driving forces in the X-axis direction and the Y-axis direction (see FIG. 16). The pair of movers 22b and the stator 26b constitute the XY linear motor 28B that generates driving forces in the X-axis direction and the Y-axis direction (see FIG. 16). The slider 10 is driven by the XY linear motor 28A and the XY linear motor 28B with a predetermined stroke in the X-axis direction.

In the first drive device 20A, the XY linear motor 28A and the XY linear motor 28B can generate driving forces different in magnitude in the X-axis direction. As a result, the slider 10 is driven in the θz direction. The first drive device 20A is controlled by the controller 60 (see FIG. 16). The first drive device 20A generates not only a driving force in the X-axis direction but also a driving force in the Y-axis direction. However, the first drive device 20A does not need to generate a driving force in the Y-axis direction.

A movable stage 24 includes a pair of plate members (24a, 24b) and a pair of coupling members (24c, 24d) that are arranged away from each other in the X-axis direction in a predetermined distance and extend in the Y-axis direction. The coupling members (24c, 24d) have steps formed on both sides in the Y-axis direction, respectively. The coupling members (24c, 24d) and the plate member 24a are integrated in a state where one end and the other end in the longitudinal direction of the plate member 24a are placed on the step on the −Y side of each coupling member (24c, 24d). The coupling members (24c, 24d) and the plate member 24b are integrated in a state where one end and the other end in the longitudinal direction of the plate member 24b are placed on the step on the +Y side of each coupling member (24c, 24d) (see FIG. 14B). That is, in this manner, the pair of plate members (24a, 24b) are connected by the pair of coupling members (24c, 24d) to constitute the movable stage 24 having a rectangular frame shape.

As illustrated in FIG. 14A, a pair of linear guides (27a, 27b) extending in the Y-axis direction is fixed near both ends in the X-axis direction of the upper surface of the base frame 16 (see FIG. 14B). Inside one linear guide 27a positioned on the +X side, a stator 25a of the Y-axis linear motor 29A constructed with a coil unit (or a magnet unit) and ranging over substantially the entire length in the Y-axis direction (see FIG. 14B) is housed in the vicinity of the upper surface and the −X side surface. A mover 23a is arranged to face the upper surface and the −X side surface of the linear guide 27a. The mover 23a includes a magnet unit (or a coil unit) having an L-shaped cross section, and constitutes the Y-axis linear motor 29A together with the stator 25a. On the lower surface and the +X side surface of the mover 23a, each facing to the upper surface and the −X side surface of the linear guide 27a, air bearings that eject pressurized air to the facing surface are fixed, respectively. As the air bearing fixed on the +X side surface of the mover 23a, a vacuum preload type air bearing is preferably used. The vacuum preload type air bearing balances the static pressure of pressurized air and the vacuum preload between the bearing surface and the −X side surface of the linear guide 27a to easily keep the clearance (space, gap) in the X-axis direction between the mover 23a and the linear guide 27a at a constant value.

On the upper surface of the mover 23a, two or more, for example, two X guides 19 constituted by a rectangular parallelepiped member are fixed at a predetermined interval in the Y-axis direction. Each of the two X guides 19 is connected in a non-contact manner to a slide member 21 having an inverted U-shaped cross section and constituting a uniaxial guide device together with the X guide 19. An air bearing is provided on each of the three surfaces of the slide member 21 facing the X guide 19. The two slide members 21 are fixed to the lower surface (the −Z side surface) of the coupling member 24c.

Inside the other linear guide 27b positioned on the −X side, a stator 25b of the Y-axis linear motor 29B constructed with a coil unit (or a magnet unit) is housed. The linear guide 27b is symmetrical, but is configured similarly to the linear guide 27a (see FIG. 14B). A mover 23b is arranged to face the upper surface and the +X side surface of the linear guide 27b. Similarly to the mover 23a (although symmetrical), the mover 23b includes a magnet unit (or a coil unit) having an L-shaped cross section. The mover 23b constitutes the Y-axis linear motor 29B together with the stator 25b. On the lower surface and the −X side surface of the mover 23b, each facing to the upper surface and the +X side surface of the linear guide 27b, air bearings are fixed, respectively. As the air bearing fixed on the −X side surface of the mover 23b, a vacuum preload type air bearing is used. The vacuum preload type air bearing easily keeps the clearance (space, gap) in the X-axis direction between the mover 23b and the linear guide 27b at a constant value.

Between the upper surface of the mover 23b and the lower surface of the coupling member 24d, two uniaxial guide devices each constituted by the X guide 19 and the slide member 21 connected in a non-contact manner to the X guide 19 are provided as described above.

The movable stage 24 is supported from below by the movers (23a, 23b) via each two uniaxial guide devices on the +X side and the −X side (four in total), and can move in the X-axis direction on the movers 23a and 23b. Therefore, when the slider 10 is driven in the X-axis direction by the above-described first drive device 20A, the reaction force of the driving force acts on the movable stage 24 provided with the stators (26a, 26b). As a result, the movable stage 24 moves in the direction opposite to the slider 10 according to the momentum conservation law. That is, the generation of vibrations caused by the reaction force of the driving force in the X-axis direction with respect to the slider 10 is prevented (or effectively suppressed) by the movement of the movable stage 24. That is, the movable stage 24 functions as a counter mass when the slider 10 moves in the X-axis direction. However, the movable stage 24 does not necessarily have to function as a counter mass. Note that a counter mass (not illustrated) may be additionally provided to prevent (or effectively suppress) the generation of vibrations caused by the driving force to drive the slider 10 in the Y-axis direction with respect to the movable stage 24.

The Y-axis linear motor 29A generates driving forces (electromagnetic forces) for driving the mover 23a in the Y-axis direction by the electromagnetic interaction between the mover 23a and the stator 25a. The Y-axis linear motor 29B generates driving forces (electromagnetic forces) for driving the mover 23b in the Y-axis direction by the electromagnetic interaction between the mover 23b and the stator 25b.

The driving force in the Y-axis direction generated by the Y-axis linear motors (29A, 29B) acts on the movable stage 24 via the two uniaxial guide devices on each of the +X side and the −X side. As a result, the slider 10 is driven in the Y-axis direction integrally with the movable stage 24. That is, in the embodiment, the movable stage 24, the four uniaxial guide devices, and the pair of Y-axis linear motors (29A, 29B) constitute the second drive device 20B (see FIG. 16) that drives the slider 10 in the Y-axis direction.

In the embodiment, the pair of Y-axis linear motors (29A, 29B) is physically separated from the surface plate 12, and is also vibrationally separated by the three vibration isolators 14. The linear guides (27a, 27b) each provided with the stators (25a, 25b) of the pair of the Y-axis linear motors (29A, 29B) may be configured to be movable in the Y-axis direction with respect to the base frame 16 (see FIG. 14B) to function as a counter mass when the slider 10 is driven in the Y-axis direction.

In the embodiment, the FIA (field image alignment) system, an image processing system, is used as the mark detection system MDS. For example, the mark detection method using the FIA system includes: irradiating an object mark with a broadband detection light flux generated from an illumination light source such as a halogen lamp; imaging, by using an imaging element (CCD or the like), an image of the object mark formed on a light receiving surface by reflected light from the object mark and an image of an indicator (for example, an indicator pattern on an indicator plate provided inside) (not illustrated); and outputting an imaging signal of these images.

The imaging signal from the mark detection system MDS is provided to the controller 60 via a signal processor 49 (see FIG. 16). The measurement device 100 is configured to be able to switch (select) the mark measurement conditions (also referred to as alignment measurement conditions) using the mark detection system MDS.

The alignment measurement conditions to be switched include: irradiation conditions for irradiating a detection target mark with detection light; light receiving conditions for receiving light generated from the mark; and signal processing conditions for processing a photoelectric conversion signal obtained by receiving light generated from the mark. By performing measurement while switching the alignment measurement conditions, an FBO mark and/or a DBO mark can be measured under different measurement conditions, thereby acquiring the absolute positions of two layers having a mark formed thereon and the positional deviation amount of the two layers. The irradiation conditions and the light receiving conditions are switched via the mark detection system MDS by the controller 60; and the signal processing conditions are switched via the signal processor 49 by the controller 60.

The irradiation conditions to be switched may include at least one of the wavelength of detection light with which a mark is irradiated from the optical system included in the mark detection system MDS; the light amount of the detection light; and NA and σ of the optical system. The light receiving conditions to be switched may include at least one of the order of diffracted light generated from a mark; and the wavelength of light generated from the mark.

Since a sensitive agent (resist) is applied on the upper surface of the wafer held on the slider 10, the detection light to be used preferably has a wavelength to which the resist is not photosensitive. For example, the overlay mark is preferably irradiated with broadband light to which the resist applied on the wafer is not photosensitive. The light source may be, for example, a white light source that emits light having a wavelength within a wavelength range of 350 to 850 nm.

Among the irradiation conditions, the method for switching the wavelength of the detection light to be adopted is, for example, a method of selectively setting a filter to be used on the optical path of the illumination light from the illumination light source in the wavelength selection mechanism included in the mark detection system MDS. In addition, it is possible to control the settings of an illumination field diaphragm, an illumination aperture diaphragm, and an imaging aperture diaphragm (examples thereof include an imaging aperture diaphragm having a light shield with an annular band light shielding shape and used in combination with an annular band illumination aperture diaphragm) each included in the mark detection system MDS, or the diaphragm conditions thereof. As a result, the illumination conditions (normal illumination/modified illumination), the dark field/bright field detection method, the numerical aperture NA or σ of the optical system, the illumination light amount, or the like can be set to a desired state.

The signal processing conditions to be switched include at least one of: selecting a waveform analysis (waveform processing) algorithm to be used in the signal processor 49; selecting a signal processing algorithm such as an EGA calculation model; and selecting various parameters to be used in each selected signal processing algorithm.

The FIA system capable of switching the alignment measurement conditions is disclosed in, for example, US Patent Application Publication No. 2008/0013073 and the like. The mark detection system MDS of the embodiment can also adopt the FIA system configured as disclosed in the above-described US Patent Application Publication. Note that the above-described US Patent Application Publication discloses that: the illumination aperture diaphragm is changed to an illumination aperture diaphragm having an annular band transmission unit from an illumination aperture diaphragm having an ordinary circular transmission unit; and a retardation plate is arranged at a position close to an imaging aperture diaphragm at a subsequent stage of the imaging aperture diaphragm. Furthermore, it is also disclosed that such modifications and arrangements are adopted so that the FIA system (alignment sensor) functions as a phase-contrast microscope type sensor to impart a predetermined phase difference to diffracted light of a predetermined order generated from the mark, as one of the light receiving conditions. In the embodiment, the mark detection system MDS also has an alignment autofocus function for adjusting the focal position of the optical system.

The signal processor 49 is a calculator including: an input unit configured to input information regarding an image of the overlay mark; a calculation unit configured to calculate an absolute position of at least one of the first pattern and the second pattern from the input information; and an output unit configured to output information regarding an absolute position of at least one of the first pattern and the second pattern calculated by the calculation unit. The signal processor 49 processes the imaging signal output as a detection signal from the mark detection system MDS, calculates the position information of the target mark with respect to the detection center, and outputs the position information to the controller 60. The signal processor 49 includes a program for calculating the absolute position of at least one of the first pattern and the second pattern from the input information, and a storage medium storing the program. The program may be installed in the measurement device from a program distribution server on the network or a storage medium.

In the embodiment, the signal processor 49 is illustrated as being separate from the controller 60, but the signal processor 49 and the controller 60 may be integrated with each other. For example, the controller 60 may have a function as a calculator included in the signal processor 49.

As the mark detection system MDS, a beam scanning type alignment system in which the target mark is scanned with measurement light in a predetermined direction while the slider 10 is moved in a predetermined direction may be used. Furthermore, in the embodiment, the mark detection system MDS has an alignment autofocus function. However, instead of or in addition to this, the measurement unit may include a focal position detection system, for example, an oblique incidence type multipoint focal position detection system as disclosed in U.S. Pat. No. 5,448,332.

As illustrated in FIGS. 14B and 15, the first position measurement system 30 has a head 32 arranged inside a recess formed in the upper surface of the surface plate 12 and fixed on the surface plate 12. The upper surface of the head 32 faces the lower surface of the slider 10 (the surface on which the grating RG1 is formed). A predetermined clearance (space, gap) is formed between the upper surface of the head 32 and the lower surface of the slider 10. The clearance in this paragraph may be, for example, a clearance of about several mm.

As illustrated in FIG. 16, the first position measurement system 30 includes an encoder system 33 and an interferometer system 35. The encoder system 33 irradiates the measurement unit on the lower surface of the slider 10 (the surface on which the grating RG1 is formed) with two or more beams from the head 32, and receives two or more return beams (for example, two or more diffracted beams from the grating RG1) from the measurement unit on the lower surface of the slider 10. As a result, the position information of the slider 10 can be acquired. The encoder system 33 includes an X linear encoder 33x that measures the position of the slider 10 in the X-axis direction; and a pair of Y linear encoders (33ya, 33yb) that measure the position of the slider 10 in the Y-axis direction. The interferometer system 35 includes four laser interferometers (35a, 35b, 35c, 35d).

The encoder system 33 may use a diffractive interference type head similar to the encoder head as disclosed, for example, in U.S. Pat. No. 7,238,931 and US Patent Application Publication No. 2007/288121 (hereinafter, abbreviated as head as appropriate). Note that the head includes a light source, a light receiving system (including a photodetector), and an optical system. However, in the embodiment, at least the optical system among these is arranged inside the housing of the head 32 to face the grating RG1, and at least one of the light source and the light receiving system may be arranged outside the housing of the head 32.

In the embodiment, there is a common detection point for the measurement of the position information of the slider 10 in the X-axis direction and the Y-axis direction. As the detection point, the controller 60 controls the actuators of the three vibration isolators 14 in real time at all times so that the position in the XY plane coincides with the detection center of the mark detection system MDS. The control is based on the relative position information between the mark detection system MDS and the surface plate 12 measured by the second position measurement system 50. Therefore, in the embodiment, the controller 60 uses the encoder system 33, and thereby the alignment mark on the wafer W placed on the slider 10 can be measured such that the position information of the slider 10 in the XY plane can be always measured immediately below the detection center of the mark detection system MDS (on the back surface side of the slider 10). In addition, the controller 60 measures the rotation amount of the slider 10 in the θz direction based on the difference between the measurement values of the pair of Y heads (37ya, 37yb).

In order to measure the position in the Z-axis direction and the rotation amount in the θx direction and the θy direction of the slider 10, it is sufficient that the beam can be made incident on three different points on the surface on which the grating RG1 is formed. Therefore, it is sufficient that there are three Z heads (for example, laser interferometers). Optionally, a protective glass for protecting the grating RG1 is provided on the lower surface of the slider 10; and a wavelength selection filter that allows transmission of each measurement beam from the encoder system 33 and blocks transmission of each measurement beam from the interferometer system 35 is provided on the surface of the protective glass.

As can be seen from the above description, the controller 60, using the encoder system 33 and the interferometer system 35 of the first position measurement system 30, can measure the position of the slider 10 in the six-degree-of-freedom directions. In this case, in the encoder system 33, since the optical path lengths of the measurement beams in the air are short and substantially equal to each other, the influence of air fluctuation can be almost ignored. Therefore, the encoder system 33 can measure the position information of the slider 10 in the XY plane (including the θz direction) with high accuracy. In addition, since the detection point substantially on the grating RG1 in the X-axis direction and the Y-axis direction by the encoder system 33 and the detection point on the lower surface of the slider 10 in the Z-axis direction by the interferometer system 35 coincide with the detection center of the mark detection system MDS in the XY plane, the occurrence of a so-called Abbe error, which is caused by the deviation between the detection point and the detection center of the mark detection system MDS in the XY plane, is suppressed to a substantially negligible extent. Therefore, by using the first position measurement system 30, the controller 60 can measure the position of the slider 10 in the X-axis direction, the Y-axis direction, and the Z-axis direction with high accuracy without an Abbe error, which is caused by the deviation between the detection point and the detection center of the mark detection system MDS in the XY plane.

As illustrated in FIGS. 14A and 14B, the second position measurement system 50 includes a pair of heads (52A, 52B) each provided on the lower surfaces of one end and the other end in the longitudinal direction of a head attachment member 51; and scale members (54A, 54B) arranged to face the heads (52A, 52B). The upper surface of the scale members (54A, 54B) is formed to be flush with the surface of the wafer W held by the wafer holder WH. A reflective two-dimensional grating (RG2a, RG2b) is formed on the upper surface of each scale member (54A, 54B). The two-dimensional gratings (hereinafter, abbreviated as grating) (RG2a, RG2b) both include a reflection type diffraction grating (X diffraction grating) having a periodic direction in the X-axis direction and a reflection type diffraction grating (Y diffraction grating) having a periodic direction in the Y-axis direction. The pitch of the grating lines of the X diffraction grating and the Y diffraction grating is, for example, 1 μm.

The scale member (54A, 54B) is made of a material having a low thermal expansion coefficient, for example, the above-described zero-expansion material, and is fixed on the surface plate 12 each via a support member 56 as illustrated in FIGS. 14A and 14B. In the embodiment, the dimensions of the scale member (54A, 54B) and the support member 56 are determined such that the grating (RG2a, RG2b) and the head (52A, 52B) face each other with a gap of about several mm.

As illustrated in FIG. 16, in the embodiment, the second position measurement system 50 includes two four-axis encoders (581, 582). The XZ linear encoder 58X1 and the YZ linear encoder 58Y1 constitute the four-axis encoder 581 that measures the positional information regarding the X-axis, the Y-axis, the Z-axis, and the ex directions of the surface plate 12 with respect to the mark detection system MDS (see FIG. 16). Similarly, the XZ linear encoder 58X2 and the YZ linear encoder 58Y2 constitute the four-axis encoder 582 that measures the positional information regarding the X-axis, the Y-axis, the Z-axis, and the θx directions of the surface plate 12 with respect to the mark detection system MDS (see FIG. 16). In this case, the position information of the surface plate 12 in the θy direction with respect to the mark detection system MDS is determined (measured) based on the position information of the surface plate 12 in the Z-axis direction with respect to the mark detection system MDS that is measured by each of the four-axis encoders (581, 582). The position information of the surface plate 12 in the θz direction with respect to the mark detection system MDS is determined (measured) based on the position information of the surface plate 12 in the Y-axis direction with respect to the mark detection system MDS that is measured by each of the four-axis encoders (581, 582).

The four-axis encoder 581 and the four-axis encoder 582 constitute the second position measurement system 50 that measures the position information of the surface plate 12 with respect to the mark detection system MDS in the six-degree-of-freedom directions, that is, the relative position information between the mark detection system MDS and the surface plate 12 in the six-degree-of-freedom directions. The relative position information between the mark detection system MDS and the surface plate 12 in the six-degree-of-freedom directions measured by the second position measurement system 50 is provided to the controller 60 at all times. The controller 60 controls the actuators of the three vibration isolators 14 in real time based on the relative position information such that the detection point of the first position measurement system 30 has a desired positional relationship with respect to the detection center of the mark detection system MDS. Specifically, the actuators of the three vibration isolators 14 are controlled such that the detection point of the first position measurement system 30 coincides with the detection center of the mark detection system MDS in the XY plane at, for example, the nm level, and the surface of the wafer W on the slider 10 coincides with the detection position of the mark detection system MDS. At this time, for example, the above-described straight line CL coincides with the reference axis LV. Note that, as long as the detection point of the first position measurement system 30 can be controlled to have a desired positional relationship with respect to the detection center of the mark detection system MDS, the second position measurement system 50 does not need to measure the relative position information in all of the six-degree-of-freedom directions.

FIG. 16 shows a block diagram showing the input/output relationship of the controller 60 mainly constituting the control system of a measurement device 100 according to the embodiment. The controller 60 includes a workstation (or a microcomputer) and the like, and integrally controls each component of the measurement device 100. As illustrated in FIG. 16, the measurement device 100 includes a wafer conveyance system 70 arranged in a chamber together with the components illustrated in FIG. 1. The wafer conveyance system 70 includes, for example, a horizontal articulated robot.

The measurement device described above may be a separate device independent of the lithography device. The measurement device may be arranged away from the lithography device, or may be arranged adjacent to the lithography device. Next, an example of the lithography device including an alignment detection system for detecting the above-described overlay mark will be described below.

### <Lithography Device>

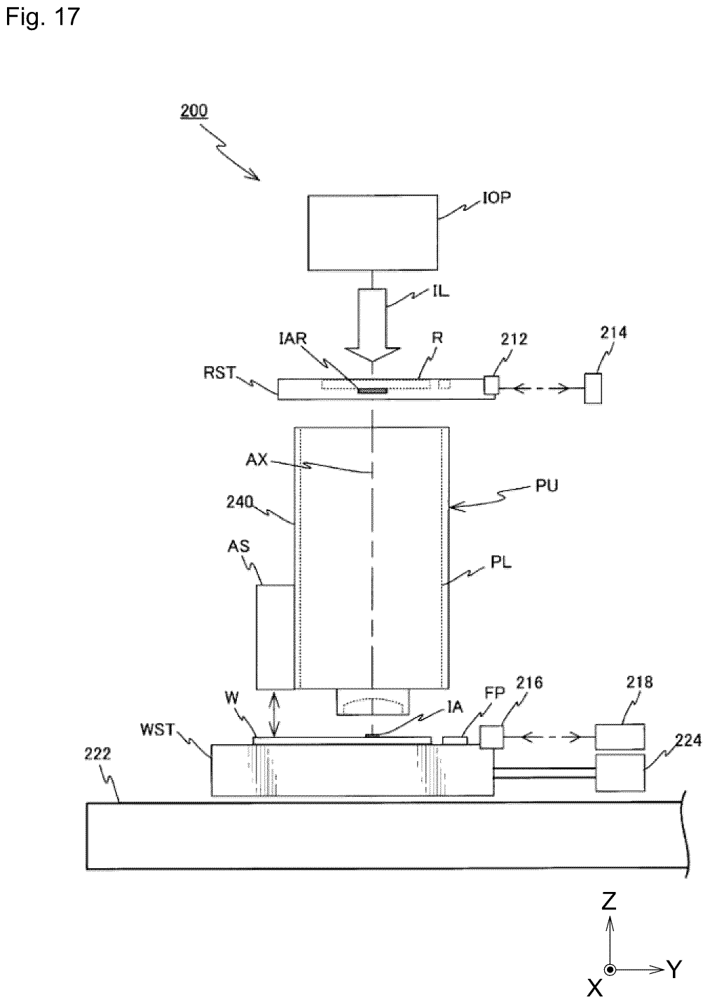

As illustrated in FIG. 17, the lithography device 200 includes an illumination system IOP, a reticle stage RST that holds a reticle R, a projection unit PU that projects an image of a pattern formed in the reticle R onto a wafer W coated with a sensitive agent (resist), a wafer stage WST that holds the wafer W and moves in the XY plane, and a control system thereof. The lithography device 200 includes a projection optical system PL having an optical axis AX in the Z-axis direction parallel to the optical axis AX1 of the mark detection system MDS described above. The lithography device 200 may be used for manufacturing a semiconductor element or for manufacturing an FPD.

The illumination system IOP includes a light source and an illumination optical system connected to the light source via a light transmission optical system, and illuminates a slit-shaped illumination area IAR elongated in the X-axis direction (the direction orthogonal to the paper surface in FIG. 17) on the reticle R set (limited) by a reticle blind (masking system) with illumination light (exposure light) IL at a substantially uniform illuminance. The configuration of the illumination system IOP is disclosed in, for example, US Patent Application Publication No. 2003/0025890. Here, examples of the illumination light IL to be used include ArF excimer laser light (wavelength: 193 nm).

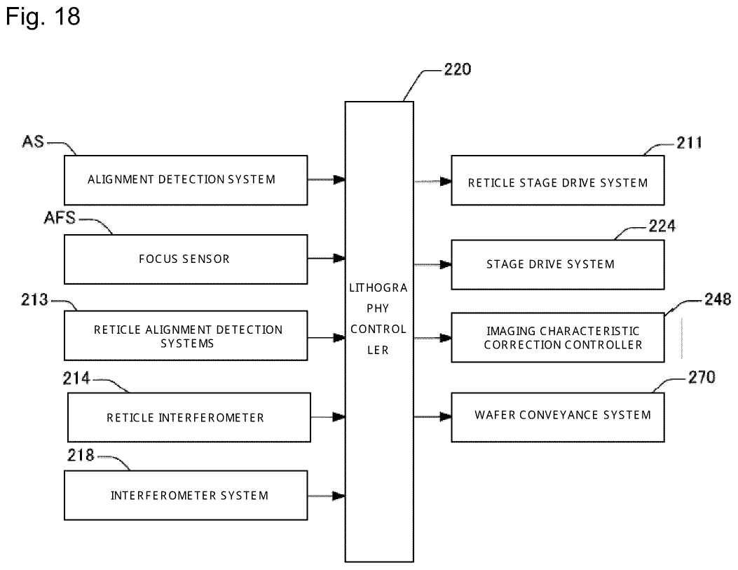

The reticle stage RST is arranged below the illumination system IOP in FIG. 9. The reticle stage RST can be minutely driven in a horizontal plane (XY plane), and can be driven in a predetermined stroke range in a scanning direction (in the Y-axis direction that is the left-right direction in FIG. 17) on a reticle stage surface plate (not illustrated), for example, by a reticle stage drive system 211 (not illustrated in FIG. 17, see FIG. 18) including a linear motor.

On the reticle stage RST, a reticle R that has a pattern region and two or more marks whose positional relationship with the pattern region is known each formed on the −Z side surface (pattern surface) is placed. The position information of the reticle stage RST in the XY plane (including rotation information in the θz direction) is being detected at all times with a resolution of, for example, about 0.25 nm by a reticle interferometer 214 via a movable mirror 212 (or a reflection surface formed on the end surface of the reticle stage RST). The measurement information of the reticle interferometer 214 is provided to a lithography controller 220 (see FIG. 18). Note that the position information of the reticle stage RST in the XY plane described above may be measured by an encoder instead of the reticle interferometer 214.

The projection unit PU is arranged below the reticle stage RST in FIG. 9. The projection unit PU includes a lens barrel 240 and a projection optical system PL held in the lens barrel 240. The projection optical system PL is, for example, both-side telecentric and has a predetermined projection magnification (for example, ¼ times, ⅕ times, ⅛ times, or the like). The reticle R is arranged such that the first surface (object surface) of the projection optical system PL and the pattern surface substantially coincide with each other, and the wafer W having the surface coated with a resist (sensitive agent) is arranged on the second surface (image surface) side of the projection optical system PL. Therefore, when the illumination area IAR on the reticle R is illuminated with the illumination light IL from the illumination system IOP, the illumination light IL passes through the reticle R, and a reduced image of the circuit pattern of the reticle R in the illumination area IAR (a reduced image of a part of the circuit pattern) is formed in the region on the wafer W conjugate to the illumination area IAR (hereinafter, also referred to as exposure region) IA via the projection optical system PL. Then, the reticle stage RST and the wafer stage WST are synchronously driven so that the reticle R is relatively moved in the scanning direction (Y-axis direction) with respect to the illumination area IAR (illumination light IL) and the wafer W is relatively moved in the scanning direction (Y-axis direction) with respect to the exposure area IA (illumination light IL), thereby scanning and exposing one shot region on the wafer W.

Exposure is performed, and the pattern of the reticle R is transferred to the shot region. The projection optical system PL to be used includes, for example, a refractive system only having two or more, for example, about 10 to 20 refractive optical elements (lens elements) arranged along the optical axis AX parallel to the Z-axis direction. Among the two or more lens elements constituting the projection optical system PL, the two or more lens elements on the object surface side (the reticle R side) are movable lenses that can be shifted in the Z-axis direction (the optical axis direction of the projection optical system PL) and driven in an inclination direction with respect to the XY plane (that is, the θx direction and the θy direction) by a drive element (not illustrated), for example, a piezo element. Then, an imaging characteristic correction controller 248 (not illustrated in FIG. 17, see FIG. 18) independently adjusts the voltage applied to each drive element based on instructions from the lithography controller 220, so that each movable lens is individually driven, and various imaging characteristics (magnification, distortion aberration, astigmatism, coma aberration, field curvature, and the like) of the projection optical system PL are adjusted. Instead of or in addition to the movement of the movable lens, a configuration in which an airtight chamber is provided between adjacent specific lens elements inside the lens barrel 240 so that an imaging characteristic correction controller 248 controls the gas pressure in the airtight chamber; or a configuration in which an imaging characteristic correction controller 248 can shift the center wavelength of the illumination light IL may be adopted. Also with these configurations, the imaging characteristics of the projection optical system PL can be adjusted.

The wafer stage WST is driven with a predetermined stroke in the X-axis direction and the Y-axis direction, and is minutely driven in the Z-axis direction, the ex direction, the θy direction, and the θz direction, on a wafer stage surface plate 222 by a stage drive system 224 including a planar motor or a linear motor (in FIG. 10, indicated by a block for convenience). The wafer W is held on the wafer stage WST by vacuum attraction or the like via a wafer holder (not illustrated). Instead of the wafer stage WST, a stage device including a first stage that moves in the X-axis direction, the Y-axis direction, and the θz direction; and a second stage that minutely moves in the Z-axis direction, the θx direction, and the θy direction on the first stage may be used.

The position information of the wafer stage WST in the XY plane (including rotation information (yawing amount (rotation amount θz in the θz direction), pitching amount (rotation amount θx in the ex direction), and rolling amount (rotation amount θy in the θy direction)) is being detected at all times with a resolution of, for example, about 0.25 nm by an interferometer system 218 via a movable mirror 216 (or a reflection surface formed on the end surface of the wafer stage WST). Note that the position information of the wafer stage WST in the XY plane may be measured by the encoder system 33 instead of the interferometer system 218.

The measurement information of the interferometer system 218 is provided to the lithography controller 220 (see FIG. 18). The lithography controller 220 controls the position of the wafer stage WST in the XY plane (including rotation in the θz direction) via the stage drive system 224 based on the measurement information of the interferometer system 218.

Although not illustrated in FIG. 17, the position and inclination amount in the Z-axis direction of the surface of the wafer W are measured, for example, by a focus sensor AFS including an oblique incidence type multipoint focal position detection system as disclosed in U.S. Pat. No. 5,448,332 (see FIG. 18). The measurement information of the focus sensor AFS is also provided to the lithography controller 220 (see FIG. 18).

In addition, a reference plate FP whose surface is flush with the surface of the wafer W is fixed on the wafer stage WST. The reference plate FP has a first reference mark to be used for baseline measurement or the like of the alignment detection system AS, a pair of second reference marks to be detected by the reticle alignment detection system, and the like, formed on the surface thereof.

On the side surface of the lens barrel 240 of the projection unit PU, an alignment detection system AS is provided to detect the alignment mark (including the above-described overlay mark) formed on the wafer W or the first reference mark. The alignment detection system AS includes an imaging unit that images an alignment mark and a light source that emits broadband light (for example, halogen lamp). As the alignment detection system AS, the image processing method, in which an image of the illuminated mark is subjected to image processing to measure the mark position, is adopted. As the image processing method, the FIA system, which is a kind of imaging alignment sensor, is used. The lithography controller 220 functions as a calculator including: an input unit configured to input information regarding an image of the overlay mark; a calculation unit configured to calculate an absolute position of at least one of the first pattern and the second pattern from the input information; and an output unit configured to output information regarding an absolute position of at least one of the first pattern and the second pattern calculated by the calculation unit. The calculator includes a program by which a lithography device performs the mark measurement method described above; and a storage medium storing the program. The program may be installed in a conventional lithography device from a program distribution server on the network or a storage medium.

The lithography device 200 further includes a pair of reticle alignment detection systems 213 (not illustrated in FIG. 17, see FIG. 18) provided above the reticle stage RST at a predetermined distance in the X-axis direction, the reticle alignment detection systems 213 being capable of simultaneously detecting a pair of reticle marks at the same Y position on the reticle R placed on the reticle stage RST. The mark detection result of the reticle alignment detection systems 213 is provided to the lithography controller 220.

FIG. 18 is a block diagram illustrating the input/output relationship of the lithography controller 220. As illustrated in FIG. 18, the lithography device 200 includes a wafer conveyance system 270 that is connected to the lithography controller 220 and conveys a wafer, and the like, in addition to the above-described components. The lithography controller 220 includes a microcomputer, a workstation, or the like, and integrally controls the entire device including the above components. The wafer conveyance system 270 includes, for example, a horizontal articulated robot.

What is claimed is:

1. A measurement method comprising:
acquiring an image of an overlay mark formed by overlaying a first pattern in which a line-and-space is repeatedly formed at a first pitch P1 in a predetermined direction in a layer on a substrate and a second pattern in which a line-and-space is repeatedly formed at a second pitch P2 different from the first pitch P1 in the predetermined direction in another layer different from the layer;
extracting a luminance signal of the overlay mark in the predetermined direction from the acquired image of the overlay mark; and
determining an absolute position of at least one of the first pattern and the second pattern in the predetermined direction from the extracted luminance signal.

2. The measurement method according to claim 1, wherein
the overlay mark includes:
a first region including a first overlay mark in which the first pattern is formed below the second pattern, and the formed second pattern is overlaid on the first pattern; and
a second region including a second overlay mark in which the first pattern is formed above the second pattern, and the formed first pattern is overlaid on the second pattern; and
the determining an absolute position of at least one of the first pattern and the second pattern in the predetermined direction from the extracted luminance signal includes:
determining a first moire position X1 in the predetermined direction of a moire image formed in the first region by overlaying the first pattern and the second pattern from the luminance signal of the first overlay mark; and
determining a second moire position X2 in the predetermined direction of a moire image formed in the second region by overlaying the second pattern and the first pattern from the luminance signal of the second overlay mark.

3. The measurement method according to claim 2, wherein the first pitch P1 and the second pitch P2 are smaller than a resolution limit of an imaging unit that images the overlay mark.

4. The measurement method according to claim 2, including at least one of:
determining an absolute position AP1 in the predetermined direction of the pattern formed above from a formula (3); and
determining an absolute position AP2 in the predetermined direction of the pattern formed below from a formula (4).
$$AP 1 = \frac{P 1 X 1 + P 2 X 2}{P 1 + P 2} \qquad ( 3 )$$
$$AP 2 = \frac{P 2 X 1 + P 1 X 2}{P 1 + P 2} \qquad ( 4 )$$

5. A measurement method comprising:
acquiring an image of an overlay mark formed in a first region by overlaying a first pattern in which a line-and-space is repeatedly formed at a first pitch P1 in a predetermined direction in a layer on a substrate and a second pattern in which a line-and-space is repeatedly formed at a second pitch P2 different from the first pitch P1 in the predetermined direction in another layer different from the layer;
acquiring an image of an overlay mark formed in a second region by overlaying a third pattern in which a line-and-space is repeatedly formed at a third pitch P3 in the predetermined direction in the layer and a fourth pattern in which a line-and-space is repeatedly formed at a fourth pitch P4 different from the third pitch P3 in the predetermined direction in the other layer;
extracting a first luminance signal that is a luminance signal in the predetermined direction of the overlay mark formed in the first region from the acquired image of the overlay mark in the first region;
extracting a second luminance signal that is a luminance signal in the predetermined direction of the overlay mark formed in the second region from the acquired image of the overlay mark in the second region; and
determining an absolute position in the predetermined direction of at least one of the first pattern, the second pattern, the third pattern, and the fourth pattern from the extracted first luminance signal and second luminance signal.

6. The measurement method according to claim 5, wherein
the determining an absolute position in the predetermined direction of at least one of the first pattern, the second pattern, the third pattern, and the fourth pattern from the extracted first luminance signal and second luminance signal includes:
determining a first moire position X1 in the predetermined direction of a moire image formed in the first region by the first pattern and the second pattern from the first luminance signal; and
determining a second moire position X2 in the predetermined direction of a moire image formed in the second region by the third pattern and the fourth pattern.

7. The measurement method according to claim 5, including at least one of:
determining an absolute position AP1 in the predetermined direction of the second pattern or the fourth pattern formed in the other layer from a formula (7); and
determining an absolute position AP2 in the predetermined direction of the first pattern or the third pattern formed in the layer from a formula (8).
$$AP 1 = \frac{P 4 ( P 2 - P 1 ) X 1 + P 2 ( P 3 - P 4 ) X 2}{P 2 P 3 - P 1 P 4} \qquad ( 7 )$$
$$AP 2 = \frac{P 3 ( P 2 - P 1 ) X 1 + P 1 ( P 3 - P 4 ) X 2}{P 2 P 3 - P 1 P 4} \qquad ( 8 )$$

8. The measurement method according to claim 2, wherein the determining the first moire position in the predetermined direction or the second moire position in the predetermined direction from the luminance signal includes:
cutting out a signal length that is positive integer times a period of the moire image from the luminance signal;
preparing a basis function of a signal of the moire image;
calculating an inner product of the cut-out luminance signal and the basis function in a range of the cut-out signal length;
acquiring a frequency component of a signal of the moire image from a calculation result of the inner product to detect a phase of the acquired frequency component; and
determining the first moire position or the second moire position from the detected phase.

9. The measurement method according to claim 1, wherein the determining an absolute position in the predetermined direction of at least one of the first pattern and the second pattern from the extracted luminance signal includes at least one of:
separating a luminance signal of the first pattern; and separating a luminance signal of the second pattern, from the luminance signal.

10. The measurement method according to claim 9, wherein the separating at least one of a luminance signal of the first pattern and a luminance signal of the second pattern, from the luminance signal, includes:
cutting out a signal length that is positive integer times a period of the pattern to be separated from the luminance signal;
preparing a basis function of a luminance signal of the pattern to be separated;
calculating an inner product of the cut-out luminance signal and the basis function in a range of the cut-out signal length; and
acquiring a frequency component of a luminance signal of the pattern to be separated from a calculation result of the inner product, further including resampling the luminance signal with a data pitch, wherein the data pitch is smaller than ½ of a period of the pattern to be separated, and a positive integral multiple of the data pitch is equal to a positive integral multiple of a period of the pattern to be separated,
wherein the basis function is a sine function.

11. The measurement method according to claim 10, including:
detecting a phase from the acquired frequency component of a luminance signal of the pattern to be separated; and
determining an absolute position of the pattern from the detected phase.

12. A measurement method comprising:
generating a luminance signal in a predetermined direction of an overlay mark formed by overlaying a first pattern in which a line-and-space is repeatedly formed at a first pitch P1 in the predetermined direction in a layer on a substrate and a second pattern in which a line-and-space is repeatedly formed at a second pitch P2 different from the first pitch P1 in the predetermined direction in another layer different from the layer;
separating and extracting a luminance signal of the first pattern from the luminance signal; and
calculating an absolute position of the first pattern based on the extracted luminance signal of the first pattern.

13. The measurement method according to claim 12, wherein the overlay mark is formed by overlaying the first pattern and the second pattern in a common first region.

14. The measurement method according to claim 12, wherein the separating and extracting a luminance signal of the first pattern includes:
cutting out a signal length that is positive integer times the first pitch from the luminance signal;
preparing a basis function of a luminance change of the first pattern;
calculating an inner product of the luminance signal and the basis function in a range of the cut-out signal length; and
acquiring a frequency component of a luminance signal of the first pattern from a calculation result of the inner product; and detecting a phase of the acquired frequency component to calculate an absolute position of the first pattern.

15. The measurement method according to claim 1, wherein a first absolute position of the first pattern in the predetermined direction and a second absolute position of the second pattern in the predetermined direction are determined from the extracted luminance signal, and a relative positional deviation amount in the predetermined direction between the first pattern and the second pattern is calculated from the first absolute position and the second absolute position.

16. The measurement method according to claim 1, the predetermined direction including: a first direction; and a second direction intersecting the first direction, the measurement method including:
determining an absolute position in the first direction of at least one of the first pattern and the second pattern by using the measurement method according to claim 1; and
determining an absolute position in the second direction of at least one of the first pattern and the second pattern by using the measurement method according to claim 1.

17. The measurement method according to claim 16, wherein
a relative positional deviation amount in the first direction between the first pattern and the second pattern is calculated from the absolute positions in the first direction of the first pattern and the second pattern, and
a relative positional deviation amount in the second direction between the first pattern and the second pattern is calculated from the absolute positions in the second direction of the first pattern and the second pattern.

18. A measurement device comprising:
a stage on which the substrate having the formed overlay mark is arranged;
an imaging unit configured to image the overlay mark; and
a controller that measures and controls an absolute position of at least one of the first pattern and the second pattern by performing the measurement method according to claim 1, based on an image of the overlay mark imaged by the imaging unit.

19. A lithography device comprising:
a stage on which the substrate having the formed overlay mark is arranged;
an imaging unit configured to image the overlay mark; and
a controller that measures and controls an absolute position of at least one of the first pattern and the second pattern by performing the measurement method according to claim 1, based on an image of the overlay mark imaged by the imaging unit.

20. A calculator comprising:
an input unit configured to input information regarding an image of the overlay mark formed on the substrate;
a calculation unit configured to calculate an absolute position of at least one of the first pattern and the second pattern by performing the measurement method according to claim 1; and
an output unit configured to output information regarding an absolute position of at least one of the first pattern and the second pattern calculated by the calculation unit.

21. A storage medium storing a program by which a measurement device or a lithography device performs the measurement method according to claim 1.

22. A measurement method comprising:
receiving light from a first pattern formed in a first layer and repeating a line-and-space in a predetermined direction at a first pitch P1 and light from a second pattern formed in a second layer overlaid on the first layer and repeating a line-and-space in the predetermined direction at a second pitch P2 different from the first pitch P1 to acquire a first image; and
outputting information regarding a position of at least one pattern of the first pattern and the second pattern in the predetermined direction with respect to a predetermined coordinate of a device with which the first image is acquired, based on the first image.

23. The measurement method according to claim 22, wherein the first image has a periodic luminance in the predetermined direction.

24. The measurement method according to claim 23, comprising
receiving light from a third pattern formed in the first layer and repeating a line-and-space in the predetermined direction at a third pitch P3 and light from a fourth pattern formed in the second layer and repeating a line-and-space in the predetermined direction at a fourth pitch P4 different from the third pitch P3 to acquire a second image having a periodic luminance in the predetermined direction, wherein
the information includes information regarding a position of the at least one pattern in the predetermined direction with respect to the predetermined coordinate, based on the first image and the second image.

25. The measurement method according to claim 24, a position of the luminance of the first image in the predetermined direction with respect to the predetermined coordinate being defined as X1, and a position of the luminance of the second image in the predetermined direction with respect to the predetermined coordinate being defined as X2,
wherein the outputting information includes at least one of: determining a position AP1 of the first pattern in the predetermined direction with respect to the predetermined coordinate from a formula (7); and
determining a position AP2 of the second pattern in the predetermined direction with respect to the predetermined coordinate from a formula (8).
$$AP 1 = \frac{P 4 ( P 2 - P 1 ) X 1 + P 2 ( P 3 - P 4 ) X 2}{P 2 P 3 - P 1 P 4} \qquad ( 7 )$$
$$AP 2 = \frac{P 3 ( P 2 - P 1 ) X 1 + P 1 ( P 3 - P 4 ) X 2}{P 2 P 3 - P 1 P 4} \qquad ( 8 )$$

26. A device comprising:
a stage on which a substrate having the first layer and the second layer is arranged; and
an imaging element configured to receive the light from the first pattern and the light from the second pattern, wherein
the device performs the measurement method according to claim 22.

27. A manufacturing method comprising manufacturing a semiconductor device having two or more layers each having a pattern by using the measurement method according to claim 22.
